(19) United States
(12) Patent Application Publication
(10) Pub. No.: US 2026/0040913 A1
(43) Pub. Date: Feb. 5, 2026

(54) SEMICONDUCTOR DEVICE WITH ISOLATION STRUCTURE AND METHOD FOR FABRICATING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/816,164

(22) Filed: Aug. 27, 2024

Related U.S. Application Data
(62) Division of application No. 18/788,323, filed on Jul. 30, 2024.

(51) Int. Cl. H01L 23/48; H01L 21/768; H01L 23/528; H01L 23/532

(52) U.S. Cl. CPC H01L 23/481; H01L 21/76843; H01L 21/76859; H01L 21/76877; H01L 23/5283; H01L 23/5329

(57) ABSTRACT

The present application discloses a semiconductor device and a method for fabricating the semiconductor device. The semiconductor device includes a substrate, a plurality of through-substrate vias (TSVs), a plurality of insulating segments, and a plurality of liners. The substrate includes a first surface and a second surface opposite to the first surface. The plurality of TSVs penetrate through the substrate. Each of the insulating segments includes an embedded portion disposed in the TSV, and an extension portion disposed over the embedded portion and the first surface. The liner is disposed on a side surface of the TSV and between the side surface and the embedded portion of the insulating segment. The plurality of insulating segments and the plurality of liners are exposed by the second surface of the substrate.

### CROSS-REFERENCE TO RELATED APPLICATION

This application is a divisional application of U.S. Non-Provisional application Ser. No. 18/788,323 filed Jul. 30, 2024, which is incorporated herein by reference in its entirety.

### TECHNICAL FIELD

The present disclosure relates to a semiconductor device and a method for fabricating the semiconductor device, and more particularly, to a semiconductor device with an isolation structure and a method for fabricating the semiconductor device with the isolation structure.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to overcome in improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device comprises a substrate having a first surface and a second surface opposite to the first surface; a plurality of first through-substrate vias (TSVs) penetrating through the substrate; a plurality of first embedded portions of first insulating segments disposed in the first TSVs; and a plurality of first liners, each disposed on a side surface of the first TSV and between the side surface of the first TSV and the first insulating segment. The first insulating segments and the first liners are exposed by the second surface of the substrate.

In some embodiments, the substrate comprises a doped region disposed in the first surface of the substrate and on the side surfaces of the first TSVs.

In some embodiments, each of the first insulating segments further comprises a first extension portion disposed over the first embedded portion and the first surface of the substrate.

In some embodiments, a width of the first extension portion is greater than a width of the first embedded portion.

In some embodiments, the first insulating segments comprise a T-shaped cross-sectional profile.

In some embodiments, the first extension portion and the first embedded portion are made of a same material.

In some embodiments, the first extension portion and the first embedded portion comprise different materials.

In some embodiments, the semiconductor device further comprises a filling layer disposed over the first surface, wherein the filling layer surrounds the first extension portions of the first insulating segments.

In some embodiments, the filling layer is made of silicon nitride.

In some embodiments, the semiconductor device further comprises a word line hard mask layer disposed over the filling layer and the first extension portions of the first insulating segments.

In some embodiments, the substrate comprises a first region and a second region, wherein the plurality of first trenches are disposed in the first region.

In some embodiments, the semiconductor device further comprises a second TSV penetrating through the substrate in the second region, a second embedded portion of a second insulating segment disposed in the second TSV, and a second liner disposed on a side surface of the second TSV and between the side surface of the second TSV and the second insulating segment, wherein the second insulating segment and the second liner are exposed by the second surface of the substrate.

In some embodiments, the doped region is further disposed on the side surfaces of the second TSV.

In some embodiments, the second insulating segment further comprises a second extension portion disposed over the second embedded portion and the first surface of the substrate.

In some embodiments, a width of the second extension portion is greater than a width of the second embedded portion.

In some embodiments, the second insulating segment comprises a T-shaped cross-sectional profile.

In some embodiments, the second extension portion and the second embedded portion are made of a same material.

In some embodiments, the second extension portion and the second embedded portion comprise different materials.

In some embodiments, the width of the second embedded portion is greater than the width of the first embedded portion.

In some embodiments, the width of the second extension portion is greater than the width of the first extension portion.

Another aspect of the present disclosure provides a semiconductor device. The semiconductor device comprises a substrate; at least one isolation feature disposed in the substrate, wherein the at least one isolation feature defines a plurality of active regions; a storage capacitor disposed over the substrate; an access transistor comprising a plurality of impurity regions disposed in the active region; and a conductive feature extending from the storage capacitor into the substrate for electrically coupling the storage capacitor to the access transistor.

In some embodiments, each of the at least one isolation features comprises a first filling layer filling a trench disposed in the substrate, a second filling layer disposed within the first filling layer, and a liner layer lining an inner surface of the trench and surrounding the first filling layer.

In some embodiments, the first filling layer and the liner layer comprise a U-shaped cross-sectional profile.

In some embodiments, a top surface of the first filling layer, a top surface of the second filling layer and a top surface of the liner layer are coplanar.

In some embodiments, a bottom surface of the second filling layer is at a vertical level higher than a bottom surface of the first filling layer.

In some embodiments, the conductive feature comprises a lower portion in the substrate and an upper portion interposed between the substrate and the storage capacitor, wherein the lower portion has a first critical dimension and the upper portion has a second critical dimension greater than the first critical dimension.

In some embodiments, the first critical dimension of the lower portion of the conductive feature gradually decreases at positions of increasing distance from the upper portion.

In some embodiments, the access transistor further comprises a word line disposed in the substrate and across the active regions, wherein the impurity regions are disposed on either side of the word line, and an insulative liner sandwiched between the substrate and the word line.

In some embodiments, the semiconductor device further comprises a dielectric layer between the storage capacitor and the substrate to encapsulate the access transistor and enclose the conductive feature, a bit line buried in the dielectric layer, and a conductive plug extending from the bit line into the substrate for electrically coupling the bit line to the access transistor.

In some embodiments, the storage capacitor comprises a plurality of storage nodes respectively contacting the conductive features, a capacitor insulator encapsulating the storage nodes, and a top electrode disposed on the capacitor insulator.

Another aspect of the present disclosure provides a method for fabricating a semiconductor device. The method includes providing a substrate including a first region and a second region, wherein the substrate has a first surface and a second surface opposite to the first surface; forming a plurality of first trenches in the first region and a second trench in the second region; forming a doped region in the substrate; forming a plurality of first liners in the first trenches and a second liner in the second trench; forming a plurality of first embedded portions of first insulating segments in the first trenches and a second embedded portion of a second insulating segment in the second trench; forming a plurality of first extension portions of the first insulating segments over the first embedded portions and a second extension portion of the second insulating segment over the second embedded portion; and removing a part of the substrate from the second surface to expose the first insulating segments, the first liners, the second insulating segment and the second liner.

In some embodiments, the first trenches and the second trench are formed by a photolithography process and an etch process.

In some embodiments, the formation of the doped region comprises performing an implantation process above the first surface of the substrate.

In some embodiments, the formation of the first liners and the second liner comprises depositing a liner layer on the first surface, on side surfaces of the first trenches, on a side surface of the second trench, and on bottom surfaces of the first trenches and the second trench, and performing an etch process on the liner layer to form the first liners and the second liner.

In some embodiments, the formation of the first embedded portions and the second embedded portion comprises depositing a first insulating layer in the first trenches and the second trench and covering the first surface of the substrate, and performing a planarization process to remove a part of the first insulating layer over the first surface of the substrate.

In some embodiments, the formation of the first extension portions and the second extension portion comprises depositing a second insulating layer over the first surface of the substrate, performing a photolithography process to form a second mask layer, performing an etching process in accordance with the second mask layer, and removing the second mask layer.

In some embodiments, the method further comprises forming a filling layer over the first surface of the substrate to surround the extension portion of the first insulating segments and the extension portion of the second insulating segment.

In some embodiments, the method further comprises forming a word line hard mask layer on the first extension portions, the second extension portions and the filling layer.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method for fabricating a semiconductor device in accordance with some embodiments of the present disclosure.

FIGS. 2 to 17 illustrate, in schematic cross-sectional view diagrams, a flow for fabricating a semiconductor device in accordance with some embodiments of the present disclosure.

FIG. 18 illustrates, in flowchart diagram form, a method for fabricating a semiconductor device in accordance with various embodiments of the present disclosure.

FIGS. 19 to 29 illustrate, in schematic cross-sectional view diagrams, a flow for fabricating a semiconductor device in accordance with various embodiments of the present disclosure.

FIG. 30 illustrates, in a schematic cross-sectional view, a semiconductor device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device that can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

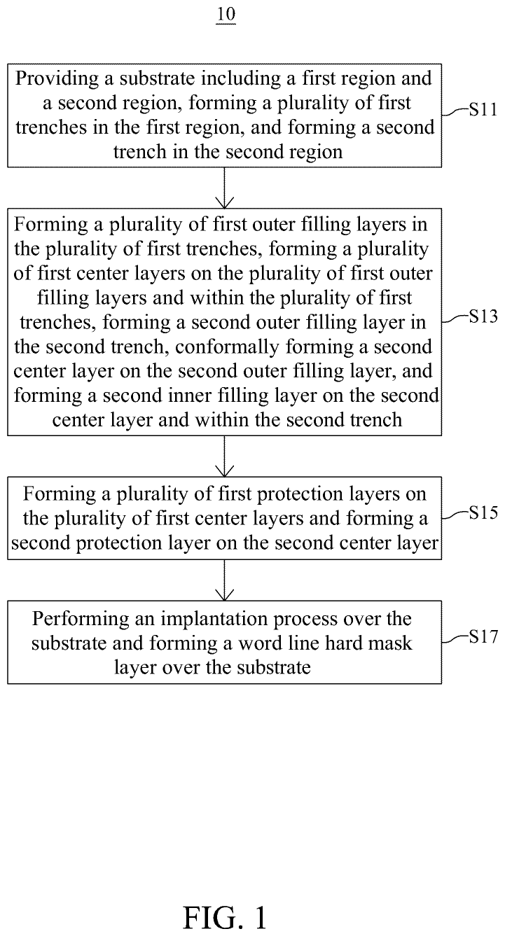

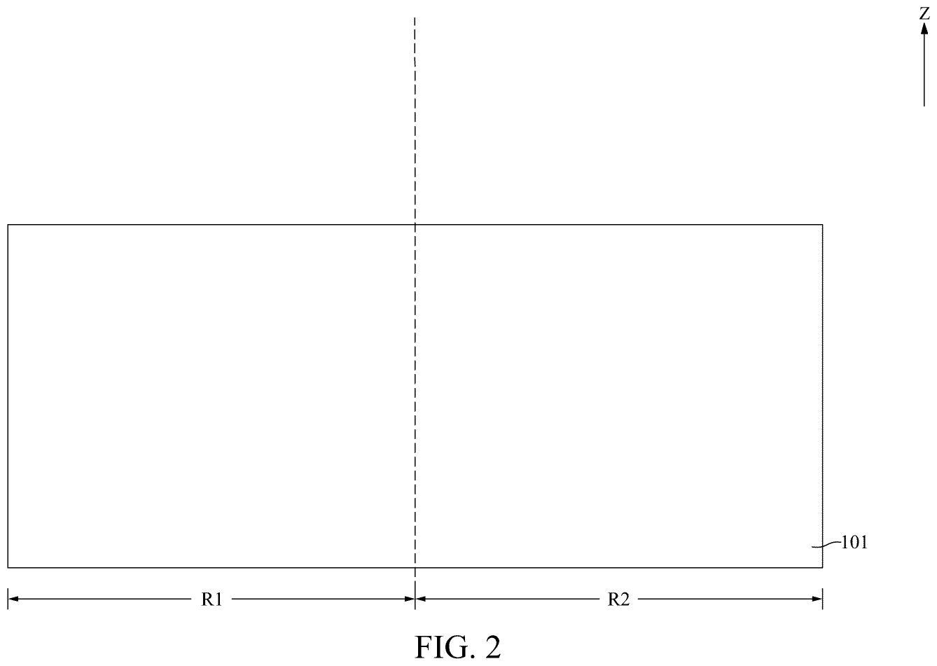

FIG. 1 illustrates, in flowchart diagram form, a method 10 for fabricating a semiconductor device 1 in accordance with some embodiment of the present disclosure. FIGS. 2 to 17 illustrate, in schematic cross-sectional view diagrams, a flow for fabricating the semiconductor device 1 in accordance with one embodiment of the present disclosure.

With reference to FIGS. 1 to 6, in step S11, a substrate 101 including a first region R1 and a second region R2 may be provided, a plurality of first trenches TR1 may be formed in the first region R1, and a second trench TR2 may be formed in the second region R2.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 101 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material such as an oxide and/or a nitride. For example, the insulator layer may be a dielectric oxide such as silicon oxide. For another example, the insulator layer may be a dielectric nitride such as silicon nitride or boron nitride. For yet another example, the insulator layer may comprise a stack of a dielectric oxide and a dielectric nitride such as a stack of, in any order, silicon oxide, silicon nitride, and/or boron nitride. The insulator layer may have a thickness between about 10 nm and about 200 nm.

It should be noted that, in the description of the present disclosure, the term “about,” when used to modify a quantity of an ingredient, component, or reactant, refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

With reference to FIG. 2, in some embodiments, the first region R1 and the second region R2 may be adjacent to each other. In some embodiments, the first region R1 and the second region R2 may be separated from each other. It should be noted that the first region R1 may comprise a portion of the substrate 101 and a space above the portion of the substrate 101. Describing an element as being disposed on the first region R1 means that the element is disposed on a top surface of the portion of the substrate 101. Describing an element as being disposed in the first region R1 means that the element is disposed in the portion of the substrate 101; however, a top surface of the element may be even with the top surface of the portion of the substrate 101. Describing an element as being disposed above the first region R1 means that the element is disposed above the top surface of the portion of the substrate 101. Accordingly, the second region R2 may comprise another portion of the substrate 101 and a space above the other portion of the substrate 101. In some embodiments, the first region R1 and the second region R2 may have different element densities, which are illustrated below.

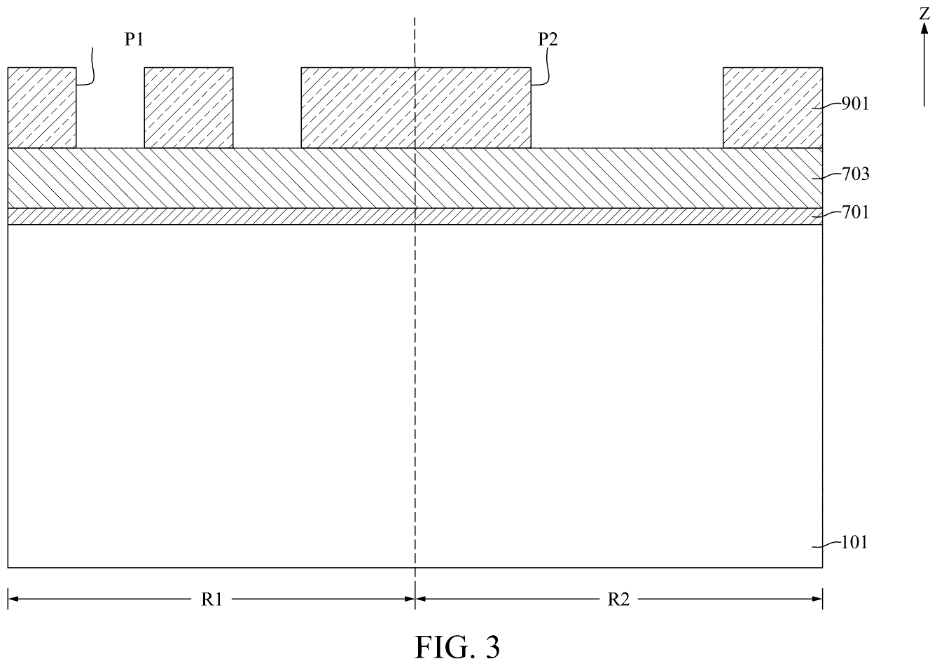

With reference to FIG. 3, a bottom hard mask layer 701 may be formed on the substrate 101. In some embodiments, the bottom hard mask layer 701 may be formed of, for example, silicon oxide. In some embodiments, the bottom hard mask layer 701 may be formed by performing a rapid thermal oxidation on the intermediate semiconductor device illustrated in FIG. 2 in an oxide/oxynitride atmosphere. In some embodiments, a temperature of the rapid thermal oxidation may be about 1000° C.

With reference to FIG. 3, a top hard mask layer 703 may be formed on the bottom hard mask layer 701. In some embodiments, the top hard mask layer 703 may be formed of, for example, silicon oxide. In some embodiments, the top hard mask layer 703 may be formed by, for example, chemical vapor deposition or plasma-enhanced chemical vapor deposition. For example, the top hard mask layer 703 may be deposited by chemical vapor deposition using a silicate or silicon source, a number of doping sources, and an ozone source. In some embodiments, the doping sources may be, for example, triethylborate, triethylphosphate, triethyphosphite, trimethylphosphate, or trimethylphosphite. In some embodiments, the silicate or silicon source may be, for example, tetramethylorthosilicate. The doping sources may result in impurity atoms such as phosphorus or boron in the top hard mask layer 703.

With reference to FIG. 3, a first mask layer 901 may be formed on the top hard mask layer 703. In some embodiments, the first mask layer 901 may be a photoresist layer and may comprise a pattern of the plurality of first trenches TR1 and the second trench TR2.

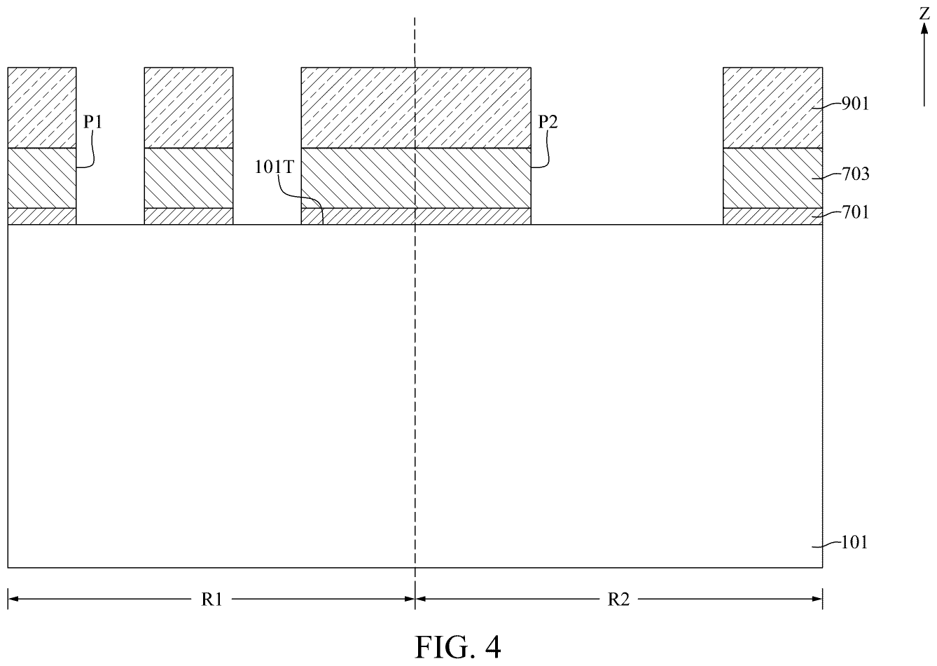

With reference to FIG. 4, a hard mask etching process may be performed using the first mask layer 901 as a mask to remove a portion of the top hard mask layer 703 and a portion of the bottom hard mask layer 701. After the hard mask etching process, the pattern of the first mask layer 901 may be transferred to the top hard mask layer 703 and the bottom hard mask layer 701. The pattern transferred from the first mask layer 901 may be referred to as a first pattern P1 and a second pattern P2. The first pattern P1 may be formed above the first region R1. The second pattern P2 may be formed above the second region R2. Portions of the top surface 101T of the substrate 101 may be exposed through the first pattern P1 and the second pattern P2.

In some embodiments, an etch rate of the top hard mask layer 703 (or an etch rate of the bottom hard mask layer 701) during the hard mask etching process may be greater than an etch rate of the substrate 101 during the hard mask etching process. For example, during the hard mask etching process, a ratio of the etch rate of the top hard mask layer 703 (or the etch rate of the bottom hard mask layer 701) to the etch rate of the substrate 101 may be between about 100:1 and about 2:1. For another example, during the hard mask etching process, a ratio of the etch rate of the top hard mask layer 703 (or the etch rate of the bottom hard mask layer 701) to the etch rate of the substrate 101 may be between about 100:1 and about 10:1.

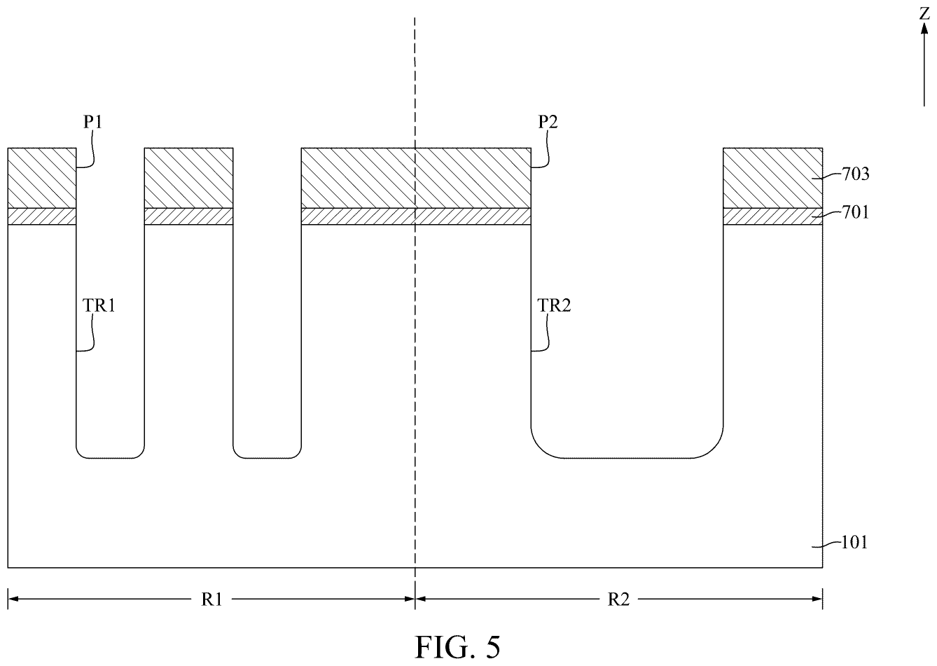

With reference to FIG. 5, the first mask layer 901 may be removed after the formation of the first pattern P1 and the second pattern P2. In some embodiments, the removal of the first mask layer 901 may include, for example, an ashing process or another applicable semiconductor process.

With reference to FIG. 5, a trench etching process may be performed, utilizing the bottom hard mask layer 701 and the top hard mask layer 703 as masks, to remove a portion of the substrate 101. This process results in the formation of the plurality of first trenches TR1 in the first region R1 of the substrate 101 and the second trench TR2 in the second region R2 of the substrate 101.

In some embodiments, an etch rate of the substrate 101 during the trench etching process may be greater than an etch rate of the top hard mask layer 703 (or an etch rate of the bottom hard mask layer 701) during the trench etching process. For example, during the trench etching process, a ratio of the etch rate of the substrate 101 to the etch rate of the top hard mask layer 703 (or the etch rate of the bottom hard mask layer 701) may be between about 100:1 and about 2:1. For another example, during the trench etching process, the ratio of the etch rate of the substrate 101 to the etch rate of the top hard mask layer 703 (or the etch rate of the bottom hard mask layer 701) may be between about 100:1 and about 10:1.

In some embodiments, the first region R1 may have a greater element density (or pattern density or feature density) compared to that of the second region R2. The element density is a value determined by dividing a number of elements (e.g., the first trenches TR1 or the second trench TR2) formed in the first region R1 (or in the second region R2) by a surface area of the respective region from a top-view perspective. From a cross-sectional perspective, a region with greater element density contains more elements, and distances between adjacent elements (or features) in such a region are less than those in a region with lower element density. As shown in FIG. 5, a presence of more first trenches TR1 is used to emphasize that the first region R1 has a greater element density than the second region R2. It should be noted that numbers of the first trenches TR1 and numbers of the second trench TR2 shown in FIG. 5 are for illustrative purposes only.

In some embodiments, a post-etching cleaning process may be performed after the formation of the plurality of first trenches TR1 and the second trench TR2. The post-etching cleaning process may include three stages with inter-stage rinses between stages. In detail, during a first stage of the post-etching cleaning process, a first cleaning solution may be applied to an intermediate semiconductor device after the formation of the plurality of first trenches TR1 and the second trench TR2. The first cleaning solution may be rinsed by a first inter-stage rinse. During a second stage of the post-etching cleaning process, a second cleaning solution may be applied to the intermediate semiconductor device and the second cleaning solution may be subsequently rinsed by a second inter-stage rinse. During a third stage of the cleaning process, a third cleaning solution may be applied to the intermediate semiconductor device and then be rinsed by a post-stage rinse.

In some embodiments, during the first stage of the post-etching cleaning process, the intermediate semiconductor device may be spun at a rate between about 10 rpm and about 2000 rpm or between about 100 rpm and about 1000 rpm. The first cleaning solution may be sprayed onto the intermediate semiconductor device to cover an entirety of a front side of the intermediate semiconductor device. Simultaneously, water or a suitable solution may be applied to a backside of the intermediate semiconductor device to clean the backside of the intermediate semiconductor device.

In some embodiments, the first cleaning solution may comprise diluted hydrofluoric acid. A concentration of the first cleaning solution may be between about 5 parts deionized water to one part hydrofluoric acid and about 1000 parts deionized water to one part hydrofluoric acid, about 300 parts deionized water to one part hydrofluoric acid, or about 50 parts deionized water to one part hydrofluoric acid. Generally, the front side of the intermediate semiconductor device may be exposed to the first cleaning solution for a time sufficient to etch either a sacrificial oxide (typically around 50 angstroms to 200 angstroms) or a native oxide (typically around 10 angstroms). In some embodiments, a processing time of the first stage of the post-etching cleaning process may be between about 20 seconds and about 50 seconds, about 40 seconds, or about 30 seconds. In some embodiments, the processing time of the first stage of the post-etching cleaning process may be between about 1 minutes and about 5 minutes.

In some embodiments, the first cleaning solution may further comprise fluoride compound(s), organic acid salt(s), and/or glyoxylic acid.

Fluorine compound(s) may be included in the first cleaning solution as a component for removing an etching residue of the trench etching process. Examples of the fluorine compound(s) may include hydrofluoric acid and ammonium or amine fluoride salts such as, for example, ammonium fluoride, ammonium hydrogen fluoride, methylamine hydrofluoride, ethylamine hydrofluoride, propylamine hydrofluoride, tetramethylammonium fluoride, tetraethylammonium fluoride, ethanolamine hydrofluoride, methylethanolamine hydrofluoride, dimethylethanolamine hydrofluoride, and triethylenediamine hydrofluoride. In some embodiments, a concentration of the fluorine compound(s) in the first cleaning solution may be determined according to a composition of the etching residue. For example, the concentration of the fluorine compound(s) may be between about 0.1 mass % and about 5 mass % of an entire composition of the first cleaning solution, or between about 0.2 mass % and about 3 mass % of the entire composition of the first cleaning solution.

The organic acid salt(s) may include, for example, ammonium oxalate, ammonium tartrate, ammonium citrate, and ammonium acetate. The organic acid salt(s) may act as a pH adjusting agent(s) or buffer agent(s) in the first cleaning solution. A concentration of the organic acid salt(s) may be between about 0.1 mass % and about 10 mass % of the entire composition of the first cleaning solution, or between about 0.3 mass % and about 5 mass % of the entire composition of the first cleaning solution.

The glyoxylic acid contained in the first cleaning solution may serve as a corrosion inhibitor.

In some embodiments, the first cleaning solution may further comprise a resist removal component. Examples of the resist removal component include tetramethylammonium hydroxide and monomethanolamine.

The first inter-stage rinse may be performed after the first stage of the post-etching cleaning process. During the first inter-stage rinse, the intermediate semiconductor device may be rotated at between about 10 rpm and about 1000 rpm while being rinsed with deionized water. In some embodiments, a rinse temperature may be between about 19° C. and about 23° C. In some embodiments, a processing time of the first inter-stage rinse may be between about 20 seconds and about 50 seconds, or about 30 seconds.

In some embodiments, the deionized water used for the first inter-stage rinse may be oxygenated or ozonated by dissolving oxygen gas or ozone gas before rinsing the intermediate semiconductor device. The dissolved oxygen or the dissolved ozone may be added to the deionized water in a concentration of greater than 1 ppm to serve as an oxidant. For example, the concentration of the dissolved oxygen or the dissolved ozone may be between about 1 ppm and about 200 ppm, or between about 2 ppm and about 20 ppm. For another example, the deionized water may be saturated with the dissolved oxygen or the dissolved ozone. Alternatively, hydrogen peroxide may be added to the deionized water in a concentration of greater than 100 ppm to serve as an oxidant. Whichever oxidant is used, it should have an oxidation potential sufficient to oxidize a most noble metal in the solution. Copper (Cu₂⁺), with a standard reduction potential of 0.3 V, is usually the most noble metal present. Therefore, a standard reduction potential of greater than 0.5 V is desired. Oxygen or ozone will solvate metal ions and prevent precipitation by oxidizing the metal ions that are in solution. This will help decrease processing time by making the first inter-stage rinse more effective.

In some embodiments, the deionized water used for the first inter-stage rinse may include carbon dioxide dissolved therein to dissipate static electricity that builds up in the deionized water. The static electricity in the deionized water may originate from the rotation of the intermediate semiconductor device. The dissolved carbon dioxide may also make the deionized water more acidic and therefore reduces any metallic contamination. In some embodiments, carbon dioxide may be dissolved in the deionized water in an amount sufficient to dissipate static electricity. For example, the amount of carbon dioxide dissolved in the deionized water may be sufficient to decrease a resistivity of the deionized water to less than 5 megaohm-cm.

In some embodiments, the deionized water used for the first inter-stage rinse may have isopropyl alcohol, or any other liquid with a surface tension less than that of the deionized water, added to it. Isopropyl alcohol may aid by making the deionized water spread out over the front side of the intermediate semiconductor device so that the chemicals are removed more quickly. Isopropyl alcohol may also help the rinse spin off of the intermediate semiconductor device during spinning. Alternatively, isopropyl alcohol vapor may be blown onto the front side of the intermediate semiconductor device during rinsing to assist the first inter-stage rinse.

In some embodiments, during the second stage of the post-etching cleaning process, the intermediate semiconductor device may be spun at a rate between about 10 rpm and about 2000 rpm or between about 100 rpm and 1000 rpm. The second cleaning solution may be sprayed onto the intermediate semiconductor device to cover the entire front side of the intermediate semiconductor device. Simultaneously, water or a suitable solution may be applied to the backside of the intermediate semiconductor device to clean the backside of the intermediate semiconductor device.

In some embodiments, the second cleaning solution may be an alkaline solution including, for example, aqueous solutions of inorganic compounds such as sodium hydroxide, potassium hydroxide and ammonium hydroxide, and aqueous solutions of organic compounds such as tetramethylammonium hydroxide and choline. The second cleaning solution may also comprise hydrogen peroxide. The purpose of the ammonium hydroxide and the hydrogen peroxide in the second cleaning solution is to remove particles and residual organic contaminants from the front side of the intermediate semiconductor device.

In the present embodiment, the second cleaning solution may include, for example, ammonium hydroxide, hydrogen peroxide, and water. The ammonium hydroxide, hydrogen peroxide, and water may be present in concentrations defined by dilution ratios of between 5/1/1 and 1000/1/1. In some embodiments, the ammonium hydroxide/hydrogen peroxide ratio may be between 0.05/1 and 5/1. In some embodiments, no hydrogen peroxide is used. The ammonium hydroxide in the second cleaning solution may comprise a 28-29% w/w concentration of ammonium hydroxide. The hydrogen peroxide in the second cleaning solution may comprise a 31-32% w/w concentration of hydrogen peroxide to water. A pH of the second cleaning solution may be between about 9 and 12 or between about 10 and 11 due to the ammonium hydroxide and the hydrogen peroxide.

In some embodiments, the second cleaning solution may further comprise dissolved hydrogen gas. The dissolved hydrogen gas in the second cleaning solution may provide cavitation (bubble creation) to the second cleaning solution. Providing cavitation to the second cleaning solution may enhance the post-etching cleaning process. In some embodiments, a concentration of the dissolved hydrogen gas may be between about 0.01 mg/L and about 5 mg/L or between about 0.1 mg/L and about 5 mg/L. In some embodiments, other suitable cavitation gases such as nitrogen, helium, argon, or oxygen may also be used. For example, dissolved oxygen having a concentration between about 1 mg/L and about 20 mg/L may be used in the second cleaning solution.

In some embodiments, a processing time of the second stage of the post-etching cleaning process may be between about 30 seconds and about 100 seconds, between about 30 seconds and 90 seconds, or between about 30 seconds and about 60 seconds. In some embodiments, a temperature of the second cleaning solution may be between about 40° C. and about 85° C.

The second inter-stage rinse may be performed after the second stage of the post-etching cleaning process. The second inter-stage rinse may be performed with a procedure similar to that of the first inter-stage rinse, and descriptions thereof are not repeated herein.

In some embodiments, during the third stage of the post-etching cleaning process, the intermediate semiconductor device may be spun at a rate between about 10 rpm and about 2000 rpm or between about 100 rpm and 1000 rpm. The third cleaning solution may be sprayed onto the intermediate semiconductor device to cover the entire front side of the intermediate semiconductor device. Simultaneously, water or a suitable solution may be applied to the backside of the intermediate semiconductor device to clean the backside of the intermediate semiconductor device.

In some embodiments, the third cleaning solution may be an acidic solution including, for example, aqueous solutions of inorganic acids such as hydrochloric acid, hydrofluoric acid, sulfuric acid and nitric acid, and aqueous solutions of organic acids such as oxalic acid, citric acid, malonic acid, malic acid, fumaric acid and maleic acid. In some embodiments, the third cleaning solution may also comprise hydrogen peroxide. A concentration of the acidic solution may be between about 0.001% and about 10% by weight or between about 0.01% and about 5% by weight. When the concentration is too low, a washing effect may be insufficient. When the concentration is too high, metal-corrosion of the washing apparatus or another related apparatus may occur.

A post-stage rinse may be performed after the third stage of the post-etching cleaning process. The post-stage rinse may be performed with a procedure similar to that of the first inter-stage rinse, and descriptions thereof are not repeated herein.

In some embodiments, the second stage and the third stage of the post-etching cleaning process are optional. In other words, in some embodiments, only the first stage of the post-etching cleaning process is performed. In some embodiments, the third stage of the post-etching cleaning process is optional. In other words, in some embodiments, only the first stage and the second stage of the post-etching cleaning process are performed.

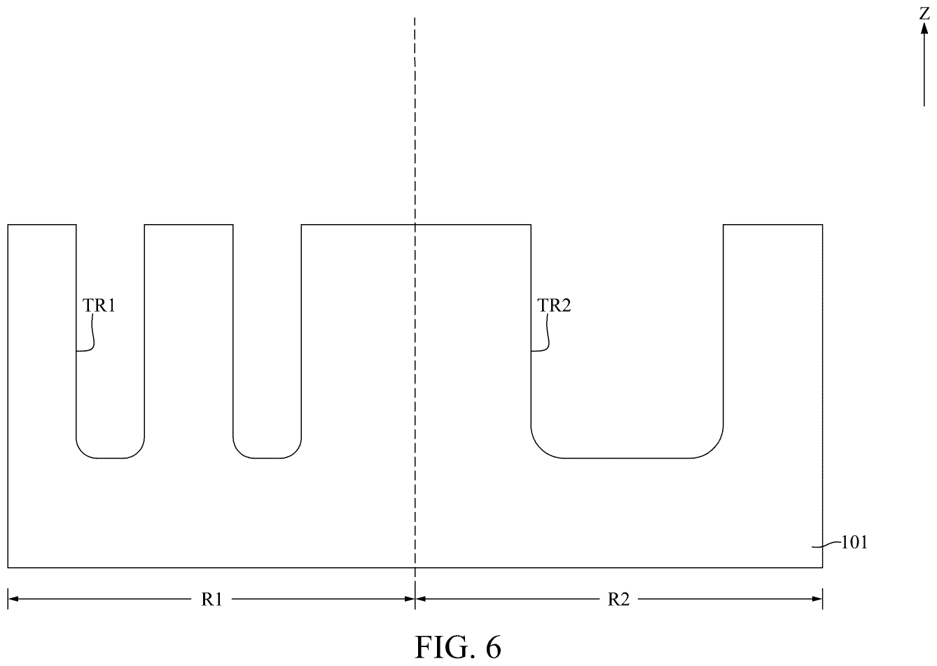

With reference to FIG. 6, the top hard mask layer 703 and the bottom hard mask layer 701 may be removed by, for example, an etching process such as a wet etching process or a dry etching process. In the present embodiment, the top hard mask layer 703 and the bottom hard mask layer 701 may be removed by a wet etching process. In some embodiments, during the etching process, a ratio of an etch rate of the top hard mask layer 703 (or an etch rate of the bottom hard mask layer 701) to an etch rate of the substrate 101 may be between about 100:1 and about 1.05:1, between about 15:1 and about 2:1, or between about 10:1 and about 2:1.

With reference to FIG. 1 and FIGS. 7 to 12, in step S13, a plurality of first outer filling layers 301 may be formed in the plurality of first trenches TR1, a plurality of first center layers 303 may be formed on the plurality of first outer filling layers 301 and within the plurality of first trenches TR1, a second outer filling layer 401 may be formed in the second trench TR2, a second center layer 403 may be conformally formed on the second outer filling layer 401, and a second inner filling layer 405 may be formed on the second center layer 403 and within the second trench TR2.

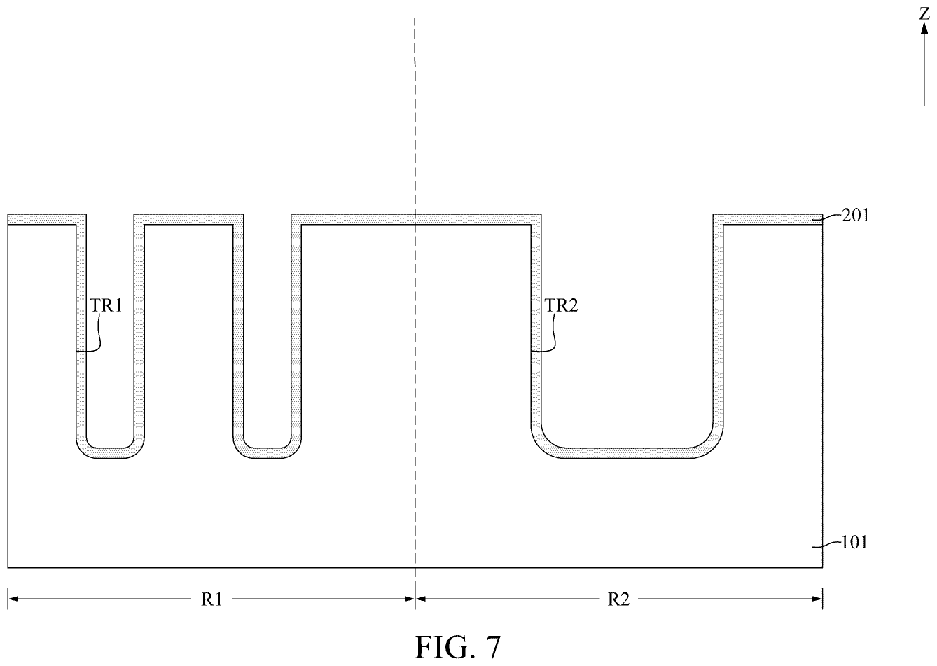

With reference to FIG. 7, a repairing layer 201 may be conformally formed on the substrate 101, in the plurality of first trenches TR1, and in the second trench TR2. In some embodiments, the repairing layer 201 may be formed of, for example, silicon. In some embodiments, the repairing layer 201 may be formed by, for example, atomic layer deposition, chemical vapor deposition, or other applicable deposition processes. In some embodiments, the repairing layer 201 may fill seams of the plurality of first trenches TR1 and the second trench TR2. In some embodiments, the repairing layer 201 may serve as a buffer or a stress-reducing layer. The repairing layer 201 may be used to mitigate mechanical stresses caused by a difference between thermal expansion coefficients of the substrate 101 and the insulating material which will be deposited later.

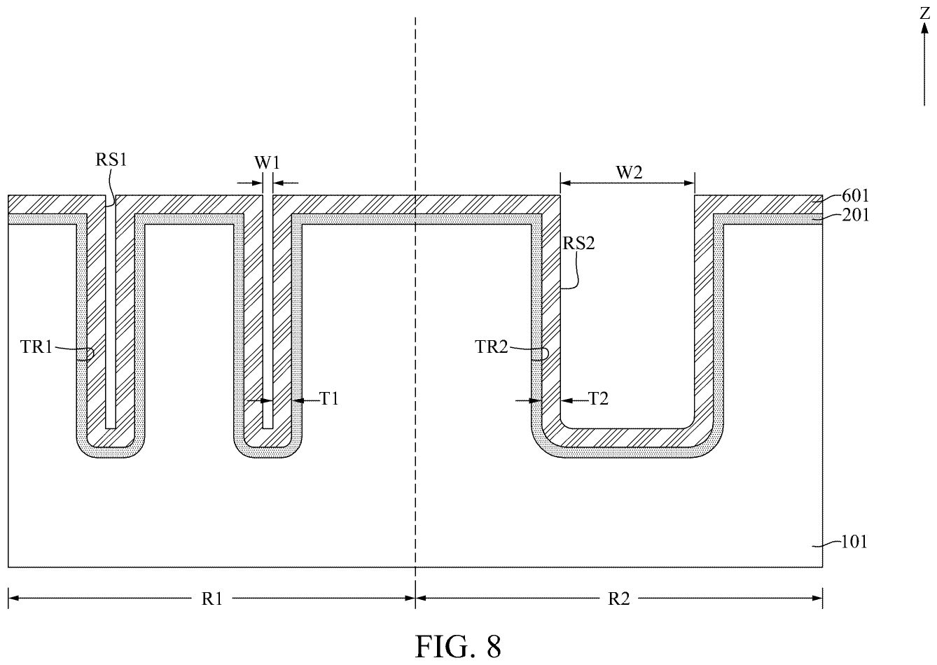

With reference to FIG. 8, a layer of first filling material 601 may be conformally formed on the repairing layer 201. The plurality of first trenches TR1 and the second trench TR2 may be only partially filled by the layer of first filling material 601. In detail, the layer of first filling material 601 may be conformally formed on a surface of the repairing layer 201 in the plurality of first trenches TR1 and the second trench TR2, thus forming upward-facing recesses RS1 (or first recesses RS1) in the plurality of first trenches TR1 and an upward-facing recess RS2 (or a second recess RS2) in the second trench TR2. In some embodiments, a top surface of the layer of first filling material 601 may vary from region to region due to a loading effect of deposition. In some embodiments, the first filling material 601 may comprise silicon oxide or other applicable insulating materials.

In some embodiments, the layer of first filling material 601 may be formed of, for example, silicon oxide. In some embodiments, the layer of first filling material 601 may be formed by, for example, chemical vapor deposition, plasma-enhanced chemical vapor deposition, or another applicable deposition process.

In some embodiments, the layer of first filling material 601 may be formed by a thermal oxidation and a subsequent deposition process. For example, the layer of first filling material 601 may be formed by initially performing a rapid thermal oxidation on the intermediate semiconductor device illustrated in FIG. 7 in an oxide/oxynitride atmosphere to conformally form a thin layer (not shown for clarity) on the repairing layer 201. Subsequently, a flowable layer (not shown for clarity) may be conformally formed on the thin layer. Lastly, the flowable layer may be turned into the layer of first filling material 601.

In some embodiments, the flowable layer may comprise compounds having unsaturated bonding such as double bonds and triple bonds. The flowable layer may be characterized as a soft jelly-like layer, a gel having liquid flow characteristics, or a liquid layer, but is not limited thereto. The flowable layer may flow into and fill small substrate gaps without forming voids or weak seams. A thermal process may be subsequently performed to transform the flowable layer into the layer of first filling material 601 by solidifying the flowable layer. A thermal process may break the unsaturated bonding into radicals, and the compounds may cross-link through the radicals. As a result, the flowable layer may be solidified. In some embodiments, a volume of the flowable layer may be reduced during the thermal process. Hence, the layer of first filling material 601 may have a density greater than that of the flowable layer. The layer of first filling material 601 may be located at a position previously occupied by the flowable layer. In other words, the layer of first filling material 601 may be conformally disposed on the top surface 101T of the substrate 101, in the plurality of first trenches TR1, and in the second trench TR2.

In some embodiments, the flowable layer may be a flowable silicon-and-nitrogen-containing layer. The flowable silicon-and-nitrogen-containing layer may be formed by mixing a carbon-free silicon-containing precursor with a radical-nitrogen precursor. A flowable nature of the flowable silicon-and-nitrogen-containing layer may allow the flowable silicon-and-nitrogen-containing layer to flow into narrow substrate gaps or narrow trenches. A temperature of the substrate 101 during the formation of the flowable silicon-and-nitrogen-containing layer may be less than 120° C., less than 100° C., less than 80° C., or less than 60° C.

The carbon-free silicon-containing precursor may be, for example, a silicon-and-nitrogen precursor, a silicon-and-hydrogen precursor, or a silicon-nitrogen-and-hydrogen-containing precursor. In some embodiments, the carbon-free silicon-containing precursor may also be oxygen-free. The lack of oxygen results in a lower concentration of silanol (Si—OH) groups in the flowable silicon-and-nitrogen-containing layer formed from the carbon-free silicon-containing precursor. Excess silanol moieties in the flowable silicon-and-nitrogen-containing layer may cause increased porosity and shrinkage during subsequent processing that removes the hydroxyl (—OH) moieties from the flowable silicon-and-nitrogen-containing layer.

In some embodiments, the carbon-free silicon-containing precursor may comprise silyl-amines such as H₂N(SiH₃), HN(SiH₃)₂, and N(SiH₃)₃. Flow rates of the silyl-amines may be greater than or about 200 sccm, greater than or about 300 sccm, or greater than or about 500 sccm. The silyl-amines may be mixed with additional gases that may act as carrier gases, reactive gases, or both. Examples of the additional gases include H₂, N₂, NH₃, He and Ar.

In some embodiments, the carbon-free silicon-containing precursor may comprise silane either alone or mixed with other silicon (e.g., N(SiH₃)₃), hydrogen (e.g., H₂), and/or nitrogen (e.g., N₂, NH₃)-containing gases.

In some embodiments, the carbon-free silicon-containing precursor may include disilane, trisilane, higher-order silanes, or chlorinated silanes, alone or in combination with silyl-amines.

The radical-nitrogen precursor may be generated by delivering ammonia to a plasma region. The radical-nitrogen precursor may be subsequently delivered to mix with the carbon-free silicon-containing precursor. The flow rate of the delivery of ammonia to the plasma region may be greater than or about 300 sccm, greater than or about 500 sccm, or greater than or about 700 sccm. In some embodiments, gases such as nitrogen and hydrogen may be employed to adjust a nitrogen:hydrogen atomic flow ratio. In some embodiments, gases such as helium or argon may be employed as a carrier gas for delivering ammonia to the plasma region.

In some embodiments, the radical-nitrogen precursor may be produced without using ammonia. Gases including one or more of hydrogen, nitrogen and hydrazine may be delivered to the plasma region to generate the radical-nitrogen precursor.

Subsequently, a curing process and an annealing process may be sequentially applied to the flowable silicon-and-nitrogen containing layer (i.e., the flowable layer) in an oxygen-containing atmosphere to convert the flowable silicon-and-nitrogen containing layer into the layer of first filling material 601 comprising silicon oxide. In some embodiments, a substrate temperature of the curing process may be below or about 400° C. For example, the substrate temperature of the curing process may be between about 100° C. and about 200° C. In some embodiments, the substrate temperature of the annealing process may be between about 500° C. and about 1100° C. In some embodiments, the oxygen-containing atmosphere may comprise one or more oxygen-containing gases such as molecular oxygen, ozone, water vapor, hydrogen peroxide, and nitrogen-oxides (e.g., nitric oxide, nitrous oxide, etc.).

Alternatively, in some embodiments, the flowable layer may be formed by reacting vapor phase precursors with co-reactants. The flowable layer may have flow characteristics that can provide consistent fill of substrate gaps of the substrate 101. Subsequently, a post-deposition treatment may be performed, and the flowable layer may be physically densified and/or chemically converted to reduce its flowability. After the post-deposition treatment, the flowable layer may be turned into the layer of first filling material 601. In some embodiments, the densified flowable layer may be considered to be solidified. In some embodiments, physically densifying the flowable layer may involve shrinking the flowable layer. In some embodiments, the post-deposition treatment may involve substituting chemicals in the flowable layer, which may result in a denser, higher-volume layer of first filling material 601.

In some embodiments, the flowable layer may comprise flowable silicon oxide, silicon nitride, or silicon oxynitride. In some embodiments, the flowable layer may comprise silicon carbide or silicon oxycarbide. In some embodiments, a chamber pressure for the formation of the flowable layer may be between about 1 Torr and 200 Torr, between 10 and 75 Torr, or about 10 Torr. In some embodiments, a substrate temperature for the formation of the flowable layer may be between about −20° C. and about 100° C., between about −20° C. and about 30° C., or between about −10° C. and about 10° C.

In some embodiments, the vapor phase precursors may include silicon-containing precursors or carbon-containing precursors. The co-reactants may include oxidants, catalyst, surfactants, or inert carrier gases.

The silicon-containing precursors may include, but are not limited to, silane, disilane, trisilane, hexasilane, cyclohexasilane, alkoxysilanes, aminosilanes, alkylsilanes, tetraisocyanatesilane (TICS), hydrogen silsesquioxane, T8-hydridospherosiloxane, or 1,2-dimethoxy-1,1,2,2-tetramethyldisilane.

The alkoxysilanes may include tetraoxymethylcyclotetrasiloxane (TOMCTS), octamethylcyclotetrasiloxane (OMCTS), tetraethoxysilane (TEOS), triethoxysilane (TES), trimethoxysilane (TriMOS), methyltriethoxyorthosilicate (MTEOS), tetramethylorthosilicate (TMOS), methyltrimethoxysilane (MTMOS), dimethyldimethoxysilane (DMDMOS), diethoxysilane (DES), dimethoxysilane (DMOS), triphenylethoxysilane, 1-(triethoxysilyl)-2-(diethoxymethylsilyl)ethane, tri-t-butoxylsilanol, hexamethoxydisilane (HMODS), hexaethoxydisilane (HEODS), or tert-butoxydisilane. The aminosilanes may include bis-tert-butylamino silane (BTBAS) or tris(dimethylamino)silane.

The carbon-containing precursors may include, but are not limited to, trimethylsilane (3MS), tetramethylsilane (4MS), diethoxymethylsilane (DEMS), dimethyldimethoxysilane, methyl-triethoxysilane (MTES), methyl-trimethoxysilane, methyl-diethoxysilane, methyl-dimethoxysilane, trimethoxymethylsilane, dimethoxymethylsilane, or bis(trimethylsilyl)carbodiimide.

The oxidants may include, but are not limited to, ozone, hydrogen peroxide, oxygen, water, alcohols, nitric oxide, nitrous dioxide, nitrous oxide, carbon monoxide, or carbon dioxide. The alcohols may include, for example, methanol, ethanol, or isopropanol.

The catalysts may include, but are not limited to, proton donor catalysts, halogen-containing compounds, mineral acids, bases, chloro-diethoxysilane, methanesulfonic acid, trifluoromethanesulfonic acid, chloro-dimethoxysilane, pyridine, acetyl chloride, chloroacetic acid, dichloroacetic acid, trichloroacetic acid, oxalic acid, benzoic acid, or triethylamine. The proton donor catalysts may include nitric acid, hydrofluoric acid, phosphoric acid, sulphuric acid, hydrochloric acid, bromic acid, carboxylic acid derivatives, ammonia, ammonium hydroxide, hydrazine, or hydroxylamine. The halogen-containing compounds may include dichlorosilane, trichlorosilane, methylchlorosilane, chlorotriethoxysilane, chlorotrimethoxysilane, chloromethyldiethoxysilane, chloromethyldimethoxysilane, vinyltrichlorosilane, diethoxydichlorosilane, or hexachlorodisiloxane. The mineral acids may include formic acid or acetic acid. The bases may include phosphine.

The surfactants may include solvents, alcohols, ethylene glycol, or polyethylene glycol. The surfactants may be used to relieve surface tension and increase wetting of reactants on the substrate surface. The surfactants may also increase a miscibility of the vapor phase precursors with other reactants.

The solvents may be non-polar or polar, and protic or aprotic. The solvents may be matched to a choice of the vapor phase precursors to improve the miscibility in the oxidants. Non-polar solvents may include alkanes and alkenes; polar aprotic solvents may include acetones and acetates; and polar protic solvents may include alcohols and carboxylic compounds.

Examples of the solvents include, but are not limited to, methanol, ethanol, isopropanol, acetone, diethylether, acetonitrile, dimethylformamide, dimethyl sulfoxide, tetrahydrofuran, dichloromethane, hexane, benzene, toluene, isoheptane and diethylether. In some embodiments, the solvents may be introduced prior to the other reactants.

The inert carrier gases may include nitrogen, helium, or argon.

The post-deposition treatment may cross-link and remove terminal groups such as —OH and —H groups in the flowable layer, thereby increasing the density and a hardness of the flowable layer. The post-deposition treatment may comprise thermal curing, exposure to a downstream or direct plasma, exposure to ultraviolet or microwave radiation, or exposure to another energy source.

When the thermal curing is used for the post-deposition treatment, a temperature of the thermal curing may be between about 200° C. and 600° C. The post-deposition treatment may be performed in an inert environment, an oxidizing environment, a nitridizing environment, or an environment that is both oxidizing and nitridizing. The inert environment may comprise argon or helium. The oxidizing environment may comprise oxygen, ozone, water, hydrogen peroxide, nitrous oxide, nitric oxide, nitrogen dioxide, carbon monoxide, or carbon dioxide. The nitridizing environment may comprise nitrogen, ammonia, nitrous oxide, nitric oxide, or nitrogen dioxide. A pressure of the thermal curing may be between about 0.1 Torr and about 10 Torr.

When the exposure to a downstream or direct plasma is used as the means of the post-deposition treatment, the plasma may be an inert plasma or a reactive plasma. The inert plasma may comprise a helium plasma or an argon plasma. The reactive plasma may comprise an oxidizing plasma including oxygen and steam, or a hydrogen-containing plasma including hydrogen and a diluent such as inert gas. In some embodiments, a temperature during the plasma exposure may be about 25° C. or greater. In some embodiments, the temperature during the plasma exposure may be between about −15° C. and about 25° C.

With reference to FIG. 8, a width W1 of the first recess RS1 may be less than a width W2 of the second recess RS2. In some embodiments, a thickness T1 of the layer of first filling material 601 formed in the first trench TR1 may be greater than a thickness T2 of the layer of first filling material 601 formed in the second trench TR2.

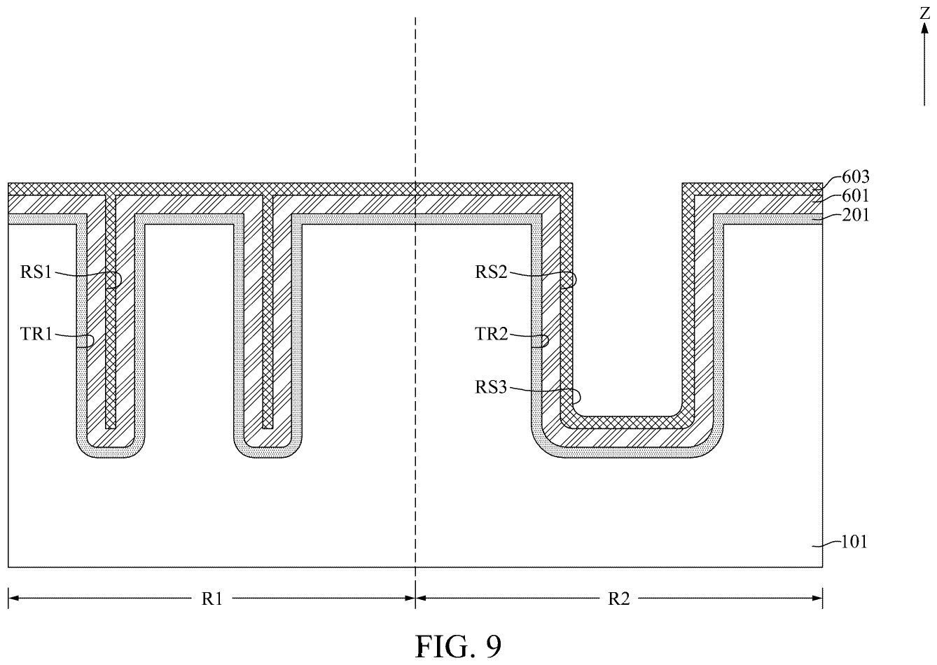

With reference to FIG. 9, a layer of second filling material 603 may be conformally formed on the layer of first filling material 601. In detail, the layer of second filling material 603 may completely fill the first recess RS1 and may only partly fill the second recess RS2. The layer of second filling material 603 may be conformally formed on the surface (i.e., in the second recess RS2) of the layer of first filling material 601 in the second trench TR2, thus forming upward-facing recesses RS3 (or third recesses RS3) in the second trench TR2.

In some embodiments, the second filling material 603 may be formed of a material having etching selectivity to the first filling material 601. In some embodiments, the second filling material 603 may comprise silicon nitride or other applicable insulating material. In some embodiments, the layer of second filling material 603 may serve as a stop layer for subsequent planarization processes or etching processes. In some embodiments, the layer of second filling material 603 may be formed by, for example, atomic layer deposition, chemical vapor deposition, or another applicable deposition process.

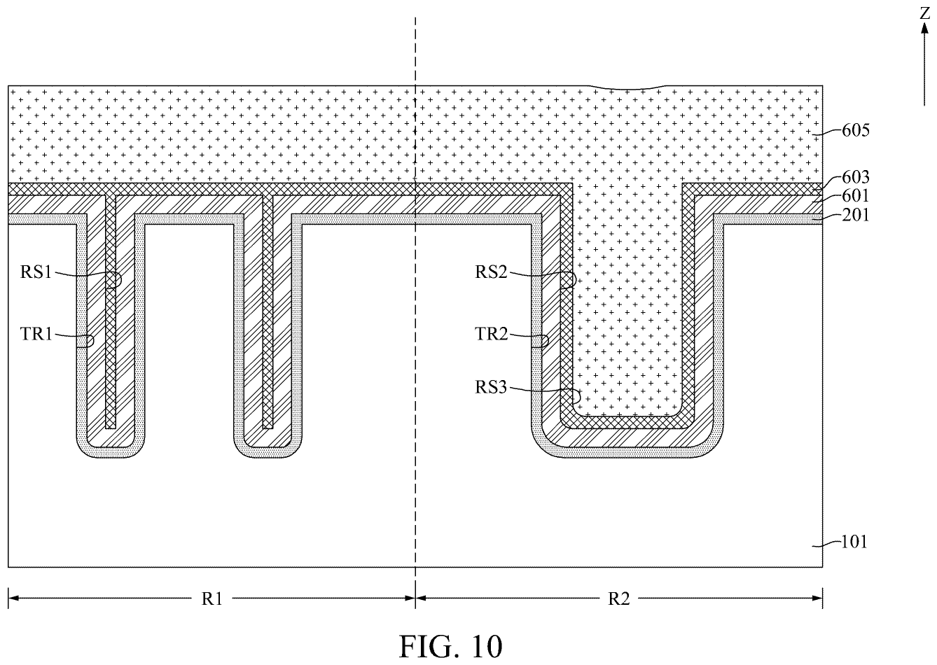

With reference to FIG. 10, a layer of third filling material 605 may be formed on the layer of second filling material 603. The layer of third filling material 605 may completely fill the third recess RS3. In some embodiments, a pit may be formed above the second trench TR2. In some embodiments, the third filling material 605 may be formed of a material having etching selectivity to the second filling material 603. In some embodiments, the third filling material 605 may include a material same as a material of the first filling material 601. In some embodiments, the third filling material 605 may comprise silicon oxide or another applicable material. In some embodiments, the layer of third filling material 605 may be formed by, for example, chemical vapor deposition, plasma-enhanced chemical vapor deposition, or other applicable deposition processes.

In some embodiments, a high aspect ratio process may be performed to deposit the layer of third filling material 605, ensuring complete filling of the third recess RS3 and covering the layer of second filling material 603. The high aspect ratio process may involve two stages. During a first stage, a low deposition rate is employed to achieve a more uniform trench fill and reduce a likelihood of void formation. In a second stage, a rapid deposition rate is used to increase overall production efficiency by reducing deposition time. This high aspect ratio process incorporates both lower and higher deposition rate stages, strategically utilizing the lower deposition rate when it is advantageous for reducing defects and the rapid deposition rate for shorter deposition time. Additionally, in some embodiments, a pressure during the high aspect ratio process may range between about 200 Torr and about 760 Torr, while a temperature may be between about 400° C. and about 570° C.

In some embodiments, a two-stage annealing process may be performed after the high aspect ratio process. During a first stage of the two-stage anneal, a lower temperature environment containing one or more oxygen-containing species, such as water, oxygen, nitric oxide, or nitrous oxide, is used. This first stage aims to rearrange and strengthen a silicon oxide network, thereby preventing formation of voids and opening of weak seams in the third recess RS3. Additionally, the lower temperature in the first stage prevents oxygen from reacting with trench walls and other parts of the substrate 101, which could lead to formation of undesirable oxide layers.

Subsequently, in a second stage of the two-stage anneal, a higher temperature environment without oxygen is employed. The second stage serves to further rearrange a structure of the third filling material 605 and drive out moisture, both of which increase a density of the layer of third filling material 605. An environment during the second stage may comprise, for example, substantially pure nitrogen, a mixture of nitrogen and noble gases (e.g., helium, neon, argon or xenon), or a substantially pure noble gas. The environment during the second stage may also include reduced levels of gases like hydrogen or ammonia. The second stage facilitates high-temperature densification without causing oxidation of the substrate 101.

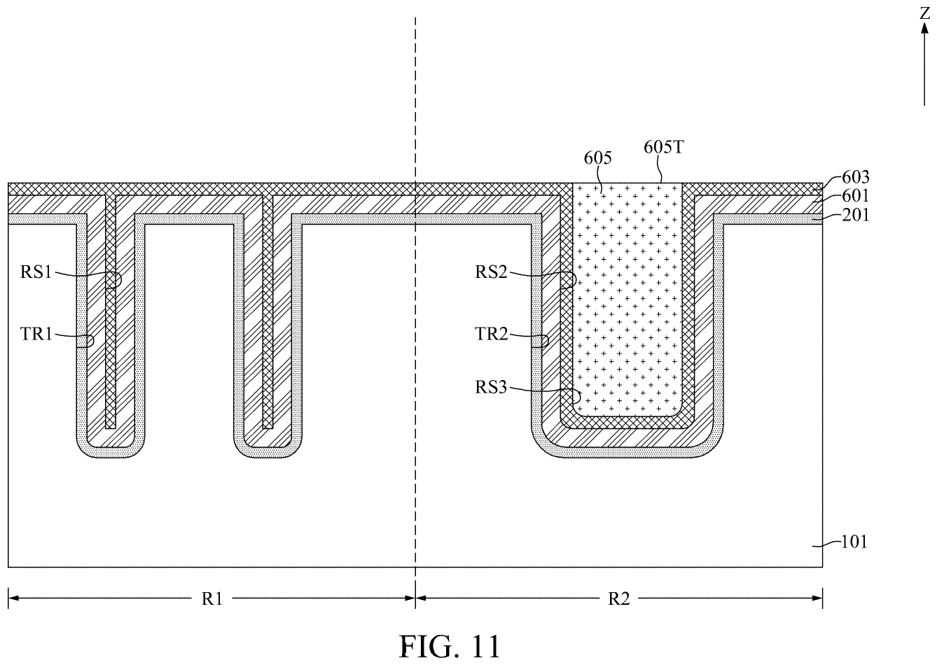

With reference to FIG. 11, after the two-stage annealing process, a planarization process, such as chemical mechanical polishing, may be performed until a top surface 603T of the layer of second filling material 603 is exposed to remove excess material and provide a substantially flat surface for subsequent processing steps. The layer of second filling material 603 may serve as a stop layer in the planarization process. The top surface 603T of the layer of second filling material 603 and a top surface 605T of the layer of third filling material 605 may be substantially coplanar at the current stage.

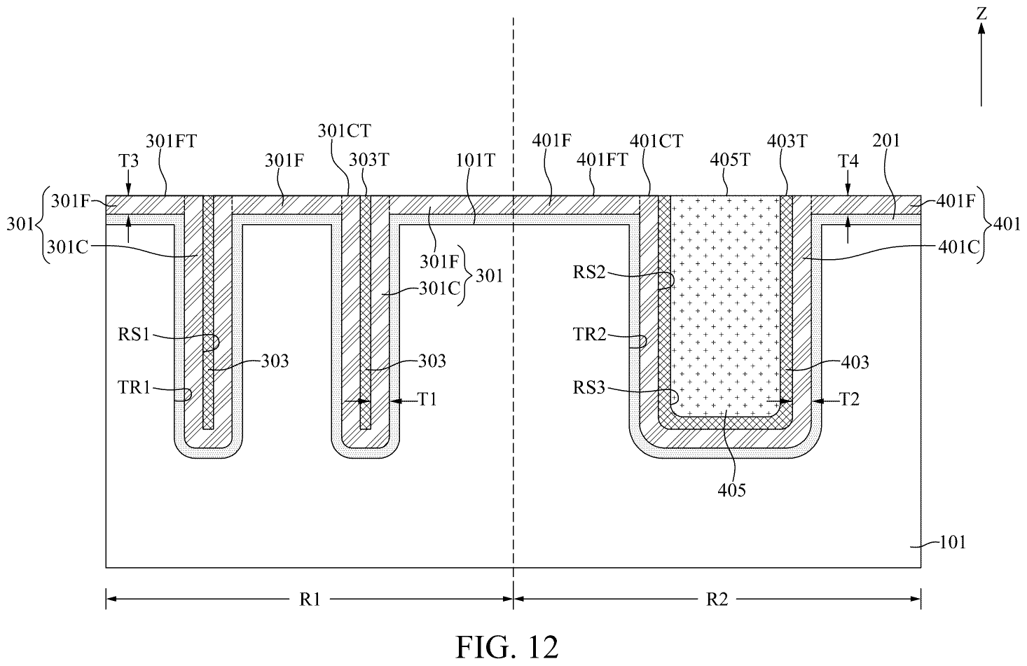

With reference to FIG. 12, an etch-back process may be performed, in which a majority of the layer of first filling material 601 is exposed and most of the second filling material 603 over the substrate 101 is removed. During the etch-back process, an etch rate of the third filling material 605 may be substantially the same as an etch rate of the second filling material 603. In some embodiments, the etch-back process may be a dry etching process. In some embodiments, a post-etching cleaning process may be performed after the etch-back process. The post-etching cleaning process may be performed with a procedure similar to that illustrated in FIG. 5, and descriptions thereof are not repeated herein.

With reference to FIG. 12, remaining portions of the first filling material 601 may be referred to as the first outer filling layer 301 and the second outer filling layer 401. In some embodiments, the first outer filling layer 301 is disposed in the first region R1 and may include a plurality of first concave portions 301C and a plurality of first flat portions 301F. The plurality of first concave portions 301C are disposed on the repairing layer 201 and within the plurality of first trenches TR1, respectively and correspondingly. Each of the plurality of first concave portions 301C may comprise a U-shaped cross-sectional profile, which forms the upward-facing first recess RS1. Ends of the plurality of first concave portions 301C may protrude above the top surface 101T of the substrate 101. In some embodiments, the first flat portion 301F is disposed on the repairing layer 201 and may be parallel to the top surface 101T of the substrate 101. The first flat portion 301F may extend between the ends of the plurality of first concave portions 301C.

With reference to FIG. 12, in some embodiments, the second outer filling layer 401 is disposed in the second region R2 and may comprise a second concave portion 401C and a second flat portion 401F. In some embodiments, the second concave portion 401C is disposed on the repairing layer 201 and in the second trench TR2. The second concave portion 401C may comprise a U-shaped cross-sectional profile, which forms the upward-facing second recess RS2. Ends of the second concave portion 401C may protrude above the top surface 101T of the substrate 101. In some embodiments, the second flat portion 401F is disposed on the repairing layer 201 and may be parallel to the top surface 101T of the substrate 101. The second flat portion 401F may extend between the ends of the second concave portion 401C. The first flat portion 301F and the second flat portion 401F may be connected and can be considered as a uniform flat layer formed on the repairing layer 201 and parallel to the top surface 101T of the substrate 101.

With reference to FIG. 12, remaining portions of the second filling material 603 may be referred to as the plurality of first center layers 303 and the second center layer 403. For brevity, clarity, and convenience of description, only one first center layer 303 is described. In some embodiments, the first center layer 303 is disposed within the first concave portion 301C and may completely fill the first recess RS1. In the current stage, a top surface 303T of the first center layer 303, a top surface 301CT of the first concave portion 301C, and a top surface 301FT of the first flat portion 301F may be substantially coplanar.

With reference to FIG. 12, the second center layer 403 may be conformally formed on the second concave portion 401C and may comprise a U-shaped cross-sectional profile, which forms the upward-facing third recess RS3. Ends of the second center layer 403 may protrude above the top surface 101T of the substrate 101. The second inner filling layer 405 may be formed within the second center layer 403 and completely fills the third recess RS3. In the current stage, a top surface 405T of the second inner filling layer 405, a top surface 403T of the second center layer 403, a top surface 401CT of the second concave portion 401C, and a top surface 401FT of the second flat portion 401F may be substantially coplanar. In some embodiments, the top surface 401FT of the second flat portion 401F and the top surface 301FT of the first flat portion 301F may be substantially coplanar.

With reference to FIG. 12, in some embodiments, a thickness T1 of the first concave portion 301C and a thickness T3 of the first flat portion 301F may be substantially the same. In some embodiments, the thickness T1 of the first concave portion 301C and the thickness T3 of the first flat portion 301F may be different. In some embodiments, a thickness T2 of the second concave portion 401C and a thickness T4 of the second flat portion 401F may be substantially the same. In some embodiments, the thickness T2 of the second concave portion 401C and the thickness T4 of the second flat portion 401F may be different. In some embodiments, the thickness T3 of the first flat portion 301F and the thickness T4 of the second flat portion 401F may be substantially the same. In some embodiments, the thickness T1 of the first concave portion 301C may be greater than the thickness T2 of the second concave portion 401C.

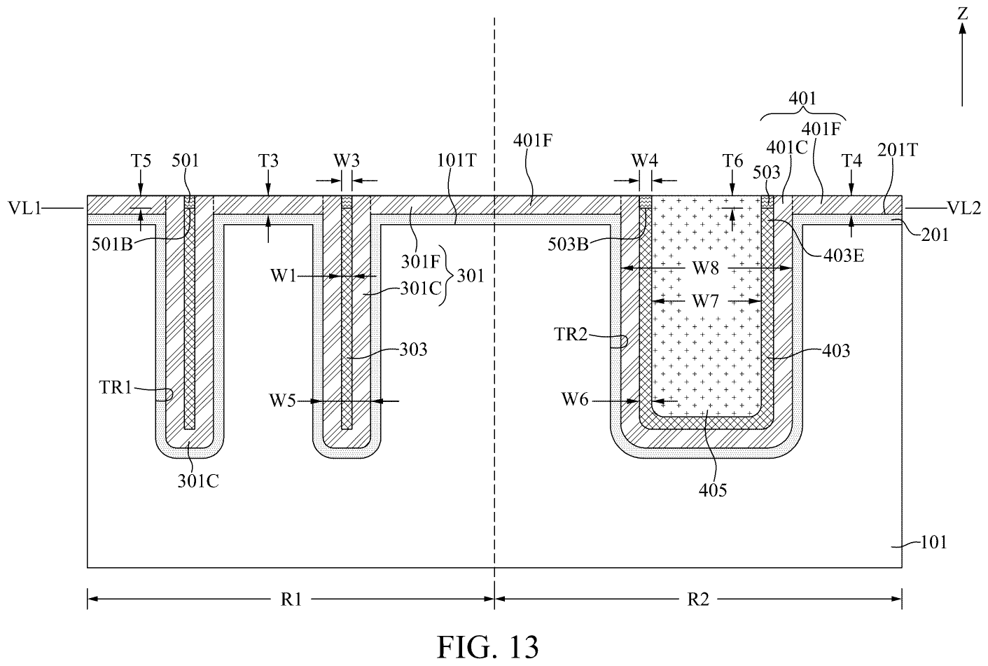

With reference to FIGS. 1 and 13, in step S15, a plurality of first protection layers 501 may be formed on the plurality of first center layers 303 and a second protection layer 503 may be formed on the second center layer 403.

With reference to FIG. 13, a surface oxidation process may be performed to oxidize top ends of the plurality of first center layers 303 and top ends of the second center layer 403. In the present embodiment, the plurality of first center layers 303 and the second center layer 403 are formed of silicon nitride. The oxidized ends of the plurality of first center layers 303 and the oxidized ends of the second center layer 403 may be referred to as the plurality of first protection layers 501 and the plurality of second protection layers 503, respectively. The plurality of first protection layers 501 may be respectively disposed on the plurality of first center layers 303. The plurality of second protection layers 503 may be respectively disposed on two ends 403E of the second center layer 403.

In some embodiments, the surface oxidation process may be a low-temperature plasma oxidation process. The low-temperature plasma oxidation process for converting silicon nitride into silicon oxide may involve several steps and specific process conditions. First, the intermediate semiconductor device illustrated in FIG. 12 may be loaded into a plasma-enhanced chemical vapor deposition (PECVD) chamber maintained at a low temperature between about 200° C. and about 400° C. Then, a gas mixture of oxygen and an inert gas, such as nitrogen or argon, may be introduced into the chamber with controlled flow rates. The flow rate of oxygen may be between about 10 standard cubic centimeters per minute (sccm) and about 100 sccm, while the inert gas flow rate can vary from about 50 sccm to about 500 sccm. Radio frequency (RF) power may be applied to generate a low-temperature plasma with a power level between about 50 watts and about 300 watts. The RF power excites the gas mixture, creating reactive species, including oxygen radicals, which play a crucial role in the low-temperature plasma oxidation process.

During the low-temperature plasma oxidation process, the oxygen radicals react with the silicon nitride surface, converting it into silicon oxide without a need for high temperatures. The low-temperature plasma oxidation process is self-limiting, meaning a reaction rate decreases as the silicon nitride layer is converted into silicon oxide. An oxidation time may be carefully controlled to achieve a desired thickness of the silicon oxide layer (i.e., the plurality of first protection layers 501 and the second protection layer 503), and the oxidation time typically ranges from a few minutes to tens of minutes, depending on required film thickness and properties. After the oxidation step, the plasma is deactivated, and a purge gas, usually nitrogen, is introduced into the chamber to remove any residual reactive species and by-products.

For brevity, clarity, and convenience of description, only one first protection layer 501 is described.

With reference to FIG. 13, a bottom surface 501B of the first protection layer 501 may be at a vertical level VL1 higher than the top surface 101T of the substrate 101 or a top surface 201T of the repairing layer 201. In some embodiments, a thickness T5 of the first protection layer 501 may be less than the thickness T3 of the first flat portion 301F. In some embodiments, a ratio of the thickness T5 of the first protection layer 501 to the thickness T3 of the first flat portion 301F may be between about 0.1 and about 0.8 or between about 0.3 and about 0.6. In some embodiments, a width W1 of the first center layer 303 and a width W3 of the first protection layer 501 may be substantially the same. In some embodiments, a ratio of the width W3 of the first protection layer 501 to a width W5 of the first concave portion 301C may be between about 0.05 and about 0.35 or between about 0.10 and about 0.30.

With reference to FIG. 13, a bottom surface 503B of the second protection layer 503 may be at a vertical level VL2 higher than the top surface 101T of the substrate 101 or the top surface 201T of the repairing layer 201. In some embodiments, a thickness T6 of the second protection layer 503 may be less than the thickness T4 of the second flat portion 401F. In some embodiments, a ratio of the thickness T6 of the second protection layer 503 to the thickness T4 of the second flat portion 401F may be between about 0.1 and about 0.8 or between about 0.3 and about 0.6. In some embodiments, a width W4 of the second protection layer 503 and a width W6 of the second center layer 403 may be substantially the same. In some embodiments, a ratio of a width W7 of the second inner filling layer 405 to a width W8 of the second concave portion 401C may be between about 0.60 and about 0.95 or between about 0.70 and about 0.90.

With reference to FIG. 13, in some embodiments, the bottom surface 501B of the first protection layer 501 and the bottom surface 503B of the second protection layer 503 may be substantially coplanar. In some embodiments, the bottom surface 501B of the first protection layer 501 and the bottom surface 503B of the second protection layer 503 may be at different vertical levels.

With reference to FIG. 1 and FIGS. 14 to 17, in step S17, an implantation process IMP may be performed over the substrate 101 and a word line hard mask layer 203 may be formed over the substrate 101.

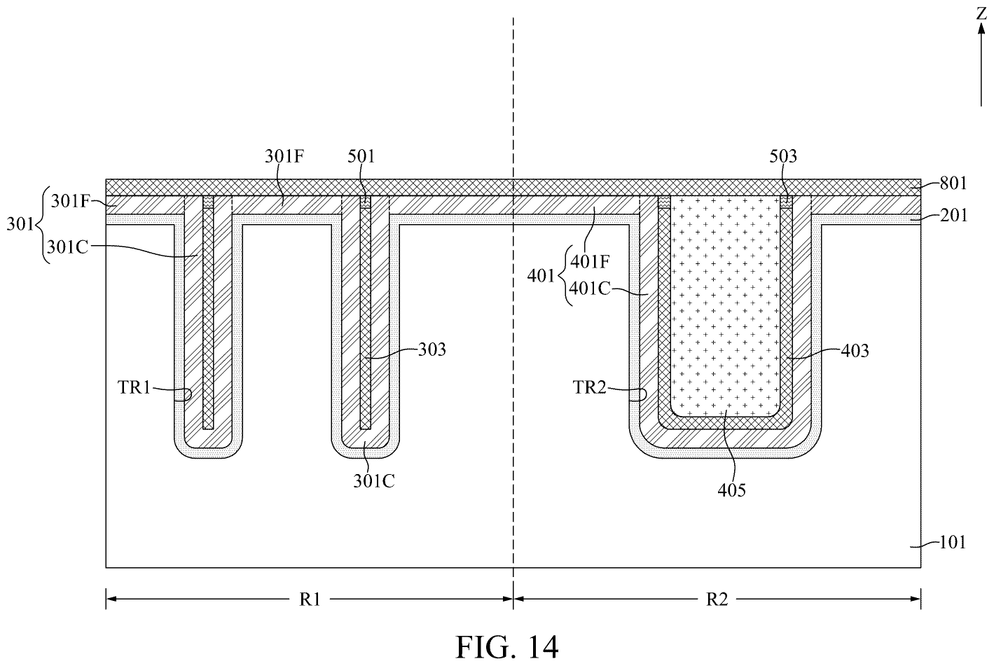

With reference to FIG. 14, a sacrificial mask layer 801 may be formed over the substrate 101 to cover the first outer filling layer 301, the first protection layer 501, the second outer filling layer 401, the second inner filling layer 405, and the second protection layer 503. In some embodiments, the sacrificial mask layer 801 may be formed of a material having high etching selectivity to the first outer filling layer 301 and the second outer filling layer 401. In some embodiments, the sacrificial mask layer 801 may be formed of a material different from materials of the first outer filling layer 301 and the second outer filling layer 401. In some embodiments, the sacrificial mask layer 801 may be formed of silicon nitride. In some embodiments, the sacrificial mask layer 801 may be formed with a procedure similar to that of the formation of the layer of second filling material 603 as illustrated in FIG. 9, and descriptions thereof are not repeated herein.

The sacrificial mask layer 801 protects the first outer filling layer 301 and the second outer filling layer 401 during subsequent implantation processes. Acting as a protective shield, the sacrificial mask layer 801 prevents potential damage to the top surfaces of the aforementioned layers, which could otherwise occur during the implantation process or during post-implantation cleaning procedures. Thus, the sacrificial mask layer 801 vitally ensures integrity of a contact area of the semiconductor device 1. Without the protection of the sacrificial mask layer 801, an active area of the semiconductor device 1 would experience reduced contact area, leading to potential reliability issues and diminished performance. Therefore, the sacrificial mask layer 801 significantly contributes to overall reliability and functionality of the semiconductor device 1.

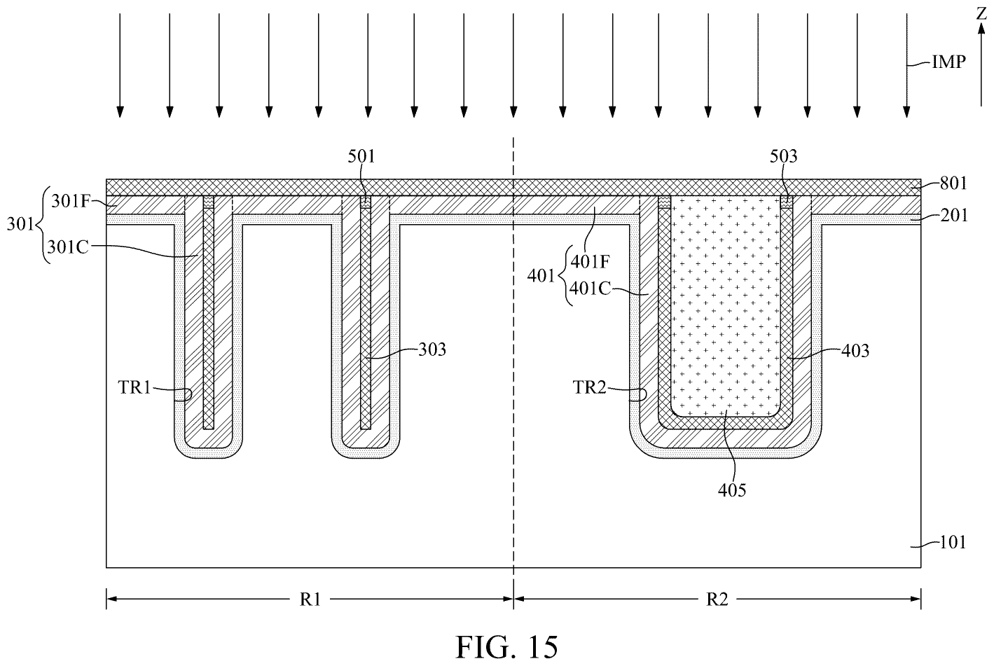

With reference to FIG. 15, the implantation process IMP may be performed using p-type dopants or n-type dopants so as to form active areas (not shown for clarity) of the semiconductor device 1 in the substrate 101. The p-type dopants may be added to an intrinsic semiconductor to create deficiencies of valence electrons. In a silicon-containing substrate, examples of p-type dopants include but are not limited to boron, aluminum, gallium, and indium. The n-type dopants may be added to an intrinsic semiconductor to contribute free electrons to the intrinsic semiconductor. In a silicon-containing substrate, examples of n-type dopants include but are not limited to antimony, arsenic, and phosphorus.

After the implantation process IMP, a post-implantation cleaning process may be performed. The post-implantation cleaning process may be a critical step to ensure the integrity and reliability of the semiconductor device 1. After the implantation process IMP, the intermediate semiconductor device may be rinsed with deionized water to remove loose particles and debris. Subsequently, a pre-cleaning step may be carried out using a diluted acid solution, typically a mixture of sulfuric acid and hydrogen peroxide in a 3:1 ratio, to eliminate metallic contaminants and/or surface oxide layers. The intermediate semiconductor device may then undergo multiple rinses with deionized water to thoroughly remove any residual cleaning solution and contaminants. An RCA clean step follows, employing an RCA-2 solution composed of deionized water, hydrogen peroxide, and ammonium hydroxide in a 5:1:1 ratio, heated to a temperature between about 70° C. and about 80° C. This step effectively removes metal ion contaminants and organic residues, and ensures a cleaner surface. The intermediate semiconductor device may be subsequently subjected to additional rinses to eliminate any remaining cleaning chemicals or particles. Finally, the intermediate semiconductor device may be dried using a spin-dryer or nitrogen gas flow to prevent watermarks or contamination.

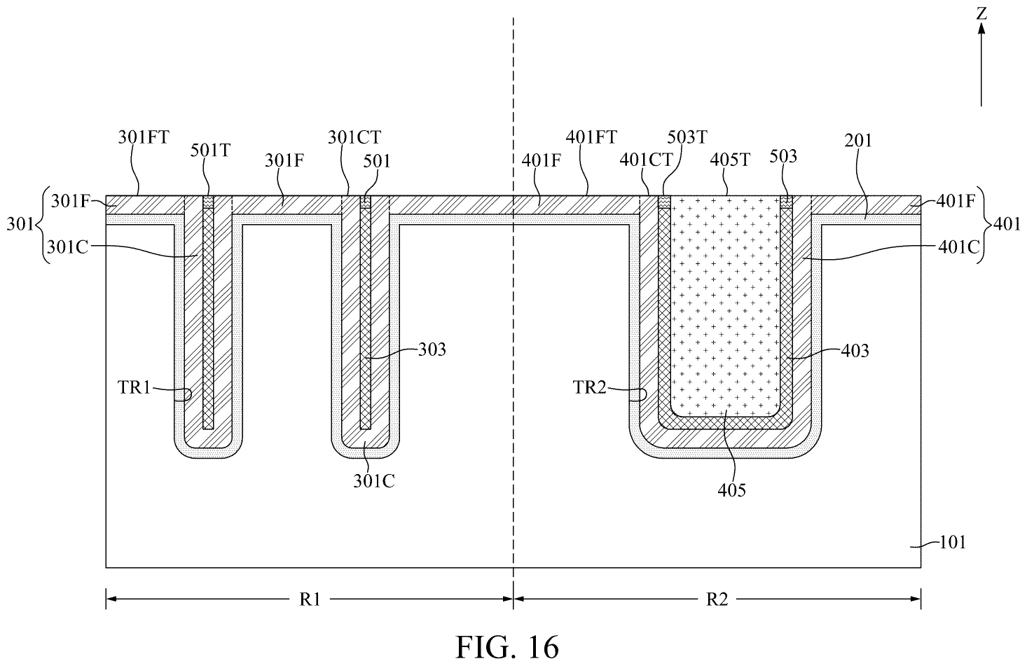

With reference to FIG. 16, the sacrificial mask layer 801 is selectively removed. This removal is achieved through an etching process with high etching selectivity to the sacrificial mask layer 801. During the etching process, an etch rate of the sacrificial mask layer 801, which may be formed of silicon nitride in some embodiments, is greater than an etch rate of the first outer filling layer 301, the second outer filling layer 401, the first protection layer 501, and the second protection layer 503, which may be formed of silicon oxide in some embodiments. For example, the etching process selectively removes silicon nitride while leaving silicon oxide intact.

The first protection layer 501 and the second protection layer 503 serve to prevent the underlying first center layer 303 and the underlying second center layer 403 from being removed during the etching process. Therefore, after the removal of the sacrificial mask layer 801, the top surfaces, namely, the top surface 301FT of the first flat portion 301F, the top surface 301CT of the first concave portion 301C, a top surface 501T of the first protection layer 501, the top surface 401FT of the second flat portion 401F, the top surface 401CT of the second concave portion 401C, the top surface 405T of the second inner filling layer 405, and a top surface 503T of the second protection layer 503, are substantially coplanar. In other words, a surface of the semiconductor device 1 may be intact and substantially flat for subsequent semiconductor processes. In some embodiments, the first protection layer 501, the first outer filling layer 301 and the first center layer 303 together configure a first isolation structure of the device 1, and the second inner filling layer 405, the second protection layer 503, the second center layer 403 and the second outer filling layer 401 together configure a second isolation structure of the device 1.

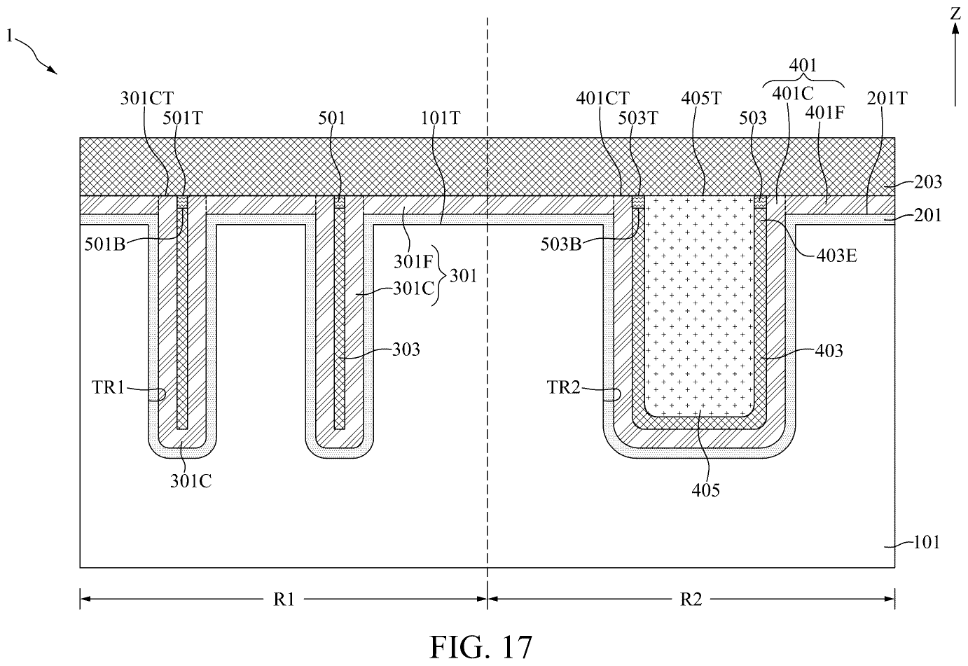

With reference to FIG. 17, a word line hard mask layer 203 may be formed on the first outer filling layer 301, the second outer filling layer 401, the first protection layer 501, the second inner filling layer 405, and the second protection layer 503. In some embodiments, the word line hard mask layer 203 may be formed of a material same as a material of the first center layer 303 or the second center layer 403. In some embodiments, the word line hard mask layer 203 may be formed of, for example, silicon nitride. In some embodiments, the word line hard mask layer 203 may be formed by, for example, chemical vapor deposition, plasma-enhanced chemical vapor deposition, or other applicable deposition processes.

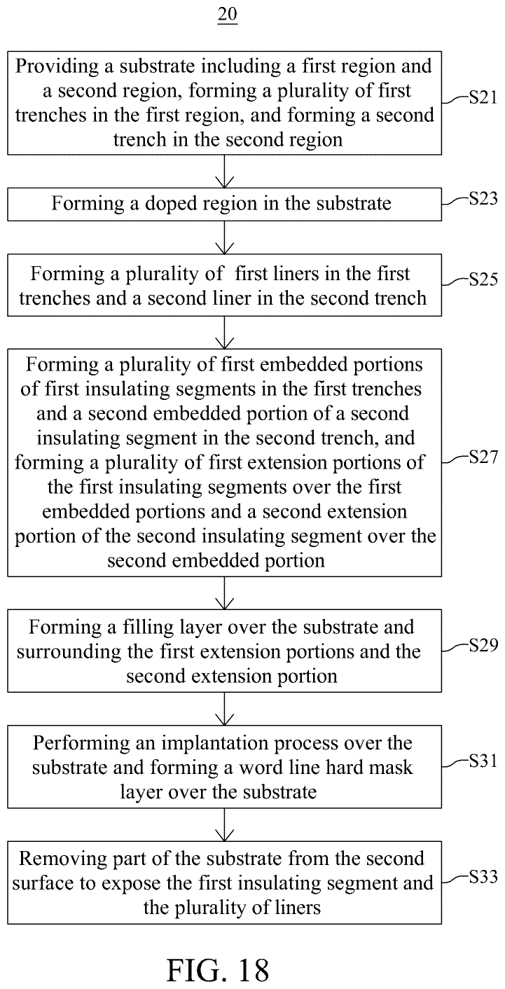

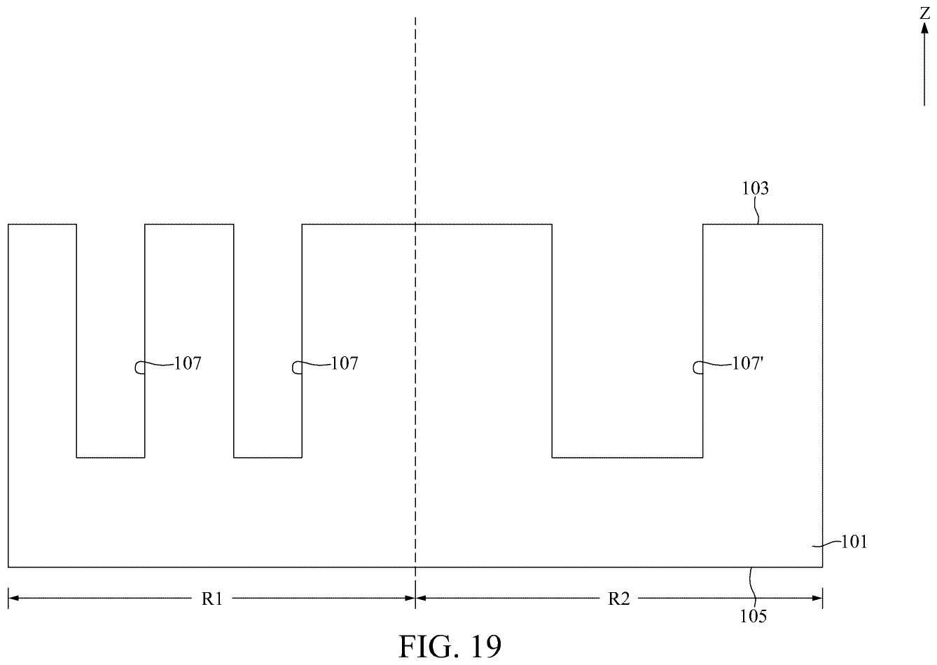

FIG. 18 illustrates, in flowchart diagram form, a method 20 for fabricating a semiconductor device 2 in accordance with various embodiments of the present disclosure. FIGS. 19 to 29 illustrate, in schematic cross-sectional view diagrams, a flow for fabricating the semiconductor device 2 in accordance with various embodiments of the present disclosure.

With reference to FIGS. 18 and 19, in step S21, a substrate 101 including a first region R1 and a second region R2 may be provided, a plurality of first trenches 107 may be formed in the first region R1, and a second trench 107′ may be formed in the second region R2.

With reference to FIG. 19, the substrate 101 may comprise a first surface 103 and a second surface 105. The first surface 103 of the substrate 101 faces upward and is parallel to the second surface 105. The second surface 105 of the substrate 101 faces downward and is opposite to the first surface 103 of the substrate 101.

With reference to FIG. 19, the first trenches 107 and the second trench 107′ may be formed in the substrate 101. The first trenches 107 and the second trench 107′ may be formed concavely in the substrate 101 with openings on the first surface 103 of the substrate 101. In some embodiments, a photolithography process may be performed by depositing a mask layer (not shown) on the first surface 103 of the substrate 101 to define positions of the first trenches 107 and the second trench 107′ on the first surface 103 of the substrate 101. Next, an etch process, such as an anisotropic dry etch process, may be performed to form the first trenches 107 and the second trench 107′ in the substrate 101.

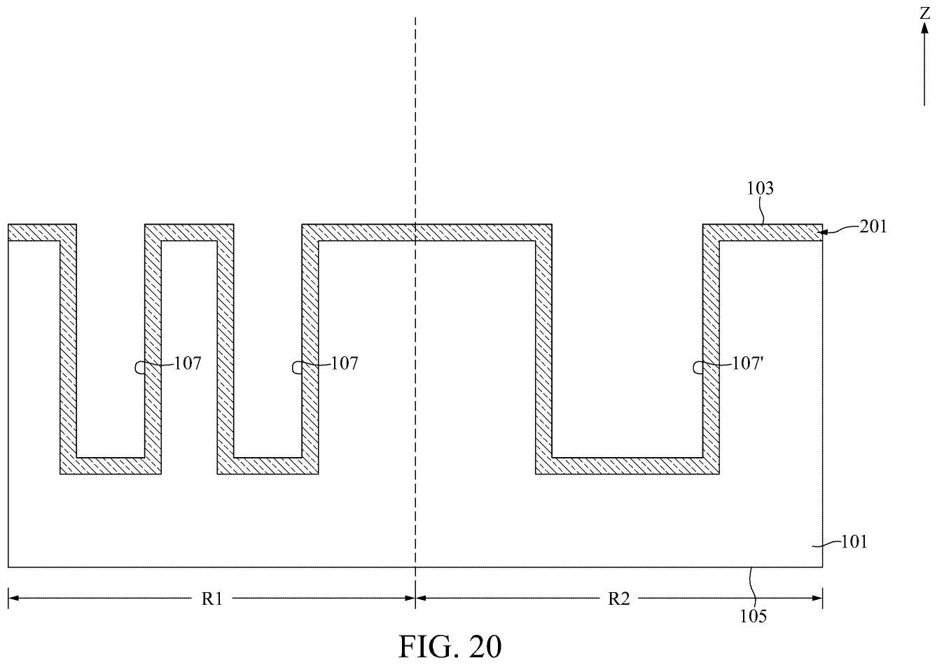

With reference to FIGS. 18 and 20, in step S23, a doped region 201 may be formed in the substrate 101. An implantation process may be performed from above the first surface 103 of the substrate 101 to form the doped region 201 in the substrate 101. The doped region 201 may be disposed in the first surface 103 of the substrate 101, on side surfaces of the first trenches 107 and the second trench 107′, and on bottoms of the first trenches 107 and the second trench 107′. A resistivity of the doped region 201 may be less than or equal to a resistivity of the substrate 101.

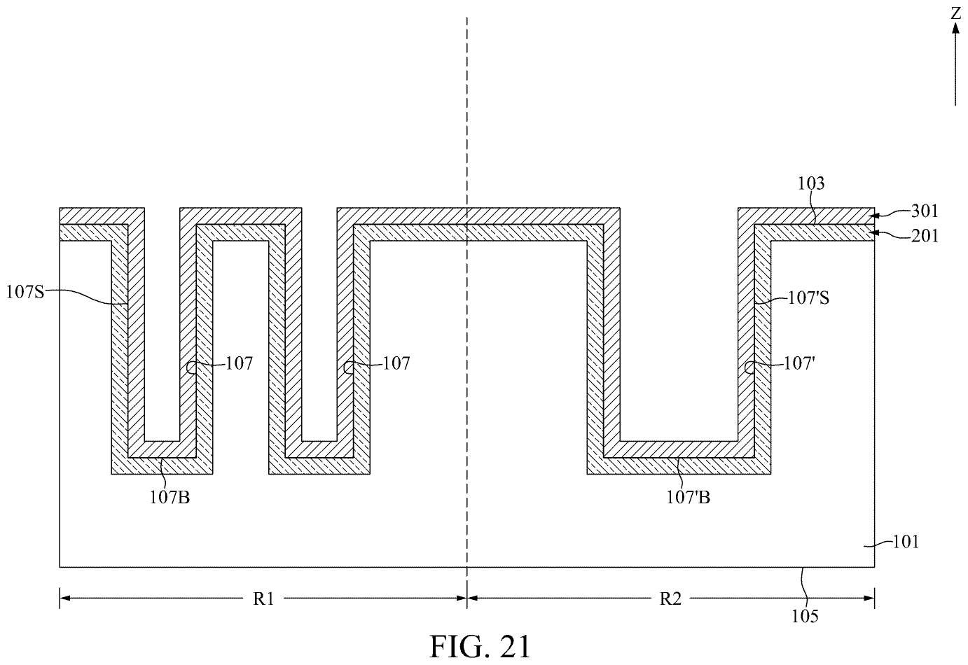

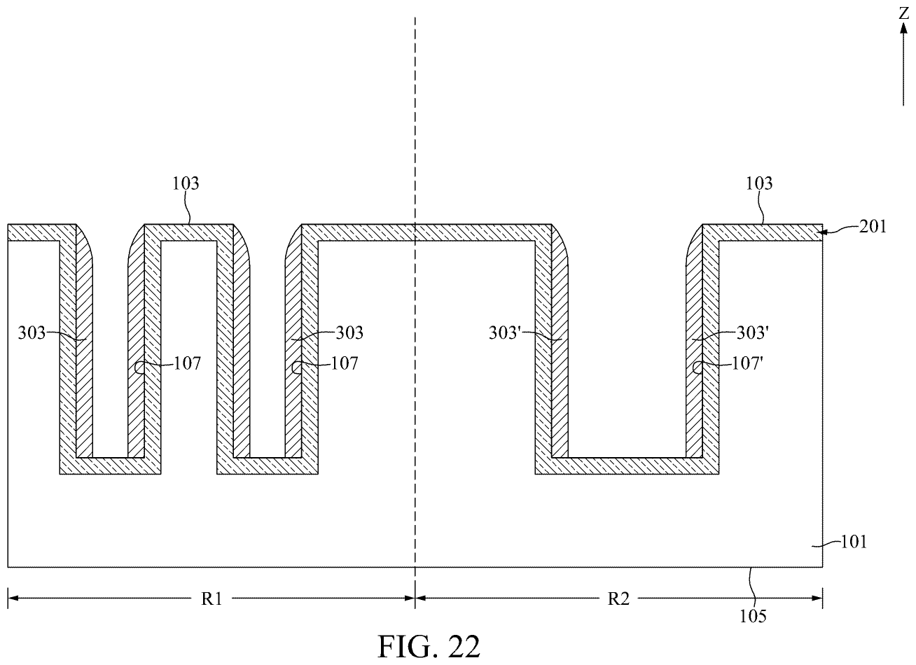

With reference to FIG. 18 and FIGS. 21 to 22, in step S25, a plurality of first liners 303 and a second liner 303′ may be formed in the first trenches 107 and the second trench 107′, respectively. With reference to FIG. 21, a liner layer 301 may be deposited on the first surface 103 of the substrate 101, on the side surfaces 107S of the first trenches 107, on the side surfaces 107'S of the second trench 107′, and on the bottoms 107B of the first trenches 107 and the bottom 107′B of the second trench 107′. The liner layer 301 may be formed of, for example, titanium, titanium nitride, titanium-tungsten alloy, tantalum, tantalum nitride, or a combination thereof. With reference to FIG. 22, an etch process, such as an anisotropic dry etch process, may be performed to form the plurality of first liners 303 attached to the side surfaces 107S (see FIG. 21) of the first trenches 107 and the second liners 303′ attached to the side surfaces 107'S (see FIG. 21) of the second trench 107′. The first liners 303 and the second liners 303′ may be electrically connected to the doped region 201.

With reference to FIG. 18 and FIGS. 23 to 26, in step S27, a plurality of first insulating segments 406 may be formed in the first trench 107 and over the substrate 101, and a second insulating segment 406′ may be formed in the second trench and over the substrate 101. The first insulating segments 406 and the second insulating segment 406′ may comprise a T-shaped cross-sectional profile. In other words, the first insulating segment 406 comprises a first embedded portion 407 disposed in the first trench 107 and a first extension portion 409 disposed on the first embedded portion 407 and over the first surface 103 of the substrate 101. The second insulating segment 406′ includes a second embedded portion 407′ disposed in the second trench 107′ and a second extension portion 409′ disposed on the second embedded portion 407′ and over the first surface 103 of the substrate 101.

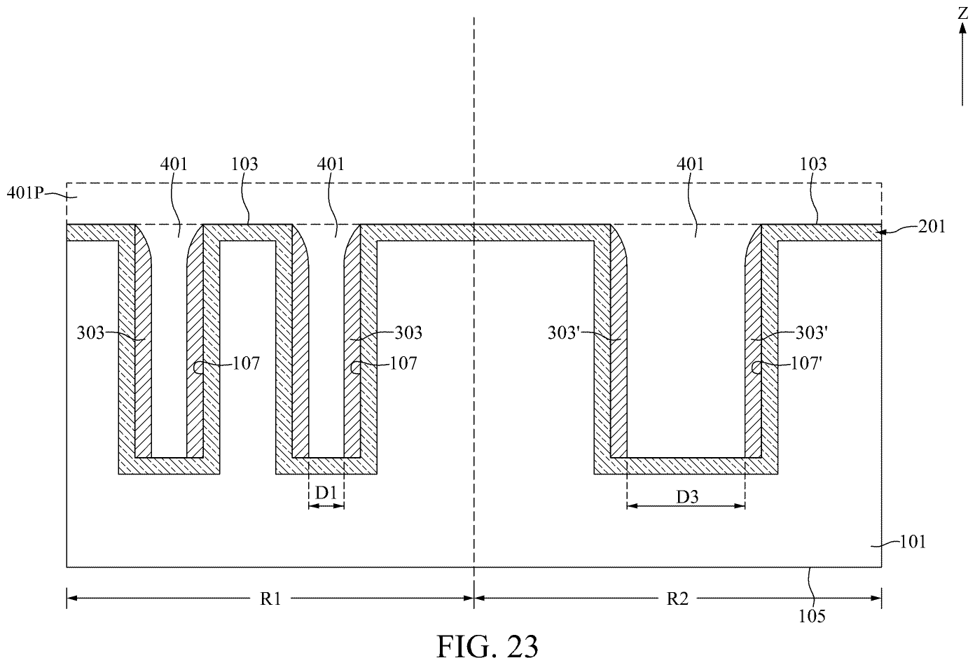

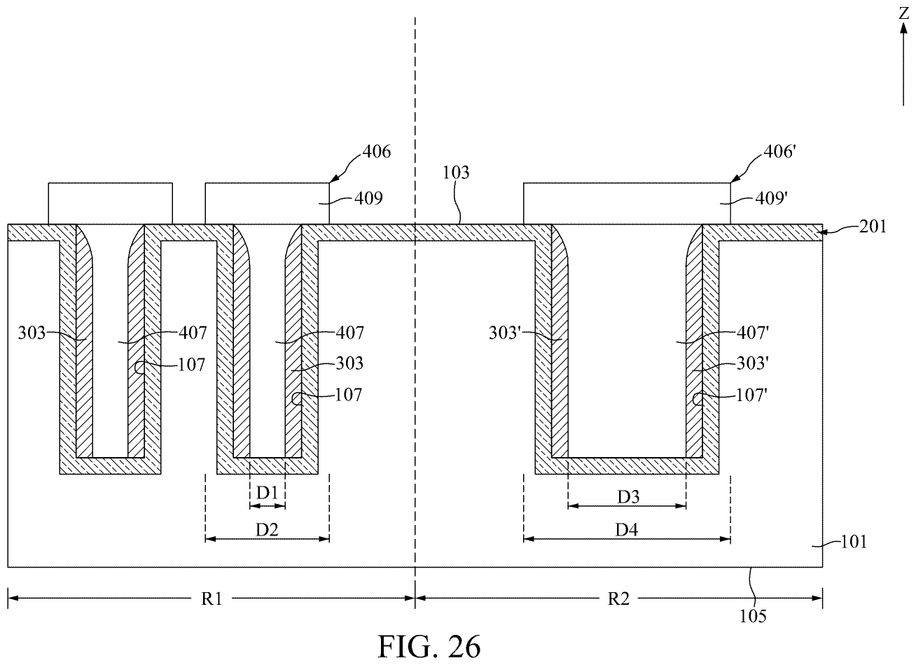

With reference to FIG. 23, a first deposition process may be performed to deposit a first insulating layer 401 in the first trenches 107 and the second trench 107′ and over the first surface 103 of the substrate 101. A planarization process, such as chemical mechanical polishing, may be performed to remove excess filling material (i.e., a part 401P of the first insulating layer 401) and provide a substantially flat surface for subsequent processing steps. The first insulating layer 401 deposited in the first trench 107 and the second trench 107′ may be respectively regarded as the first embedded portion 407 of the first insulating segment 406 and the second embedded portion 407′ of the second insulating segment 406′, as shown in FIG. 26.

The first insulating layer 401 may be formed of silicon nitride, silicon oxide, silicon oxynitride, flowable oxide, tonen silazen, undoped silica glass, borosilica glass, phosphosilica glass, borophosphosilica glass, plasma-enhanced tetra-ethyl orthosilicate, fluoride silicate glass, carbon-doped silicon oxide, xerogel, aerogel, amorphous fluorinated carbon, organo silicate glass, parylene, bis-benzocyclobutenes, polyimide, porous polymeric material, or a combination thereof, but is not limited thereto.

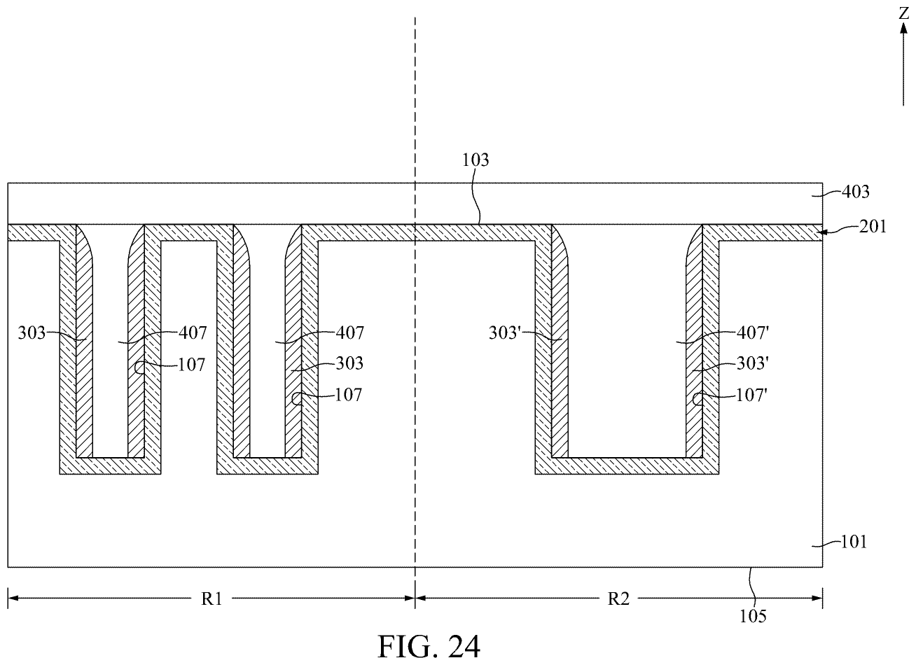

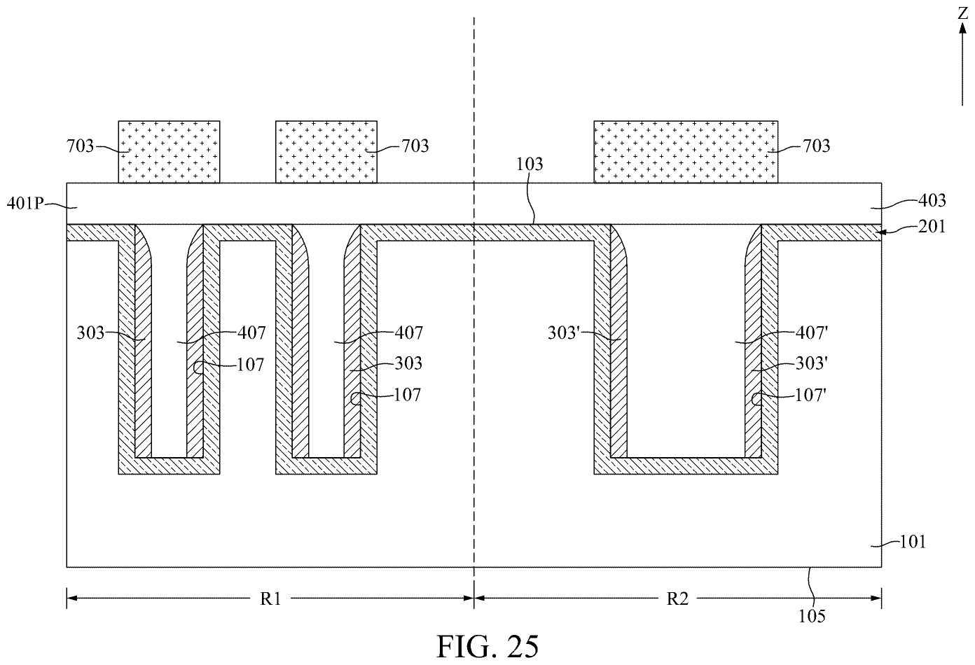

With reference to FIG. 24, a second deposition process may be performed to deposit a second insulating layer 403 over the first surface 103 of the substrate 101. The second insulating layer 403 may be preferably formed of a material same as a material of the first insulating layer 401, but is not limited thereto. With reference to FIG. 25, a photolithography process may be performed by depositing a second mask layer 703 on the second insulating layer 403 to define positions of the first extension portions 409 of the first insulating segment 406 and the second extension portion 409′ of the second insulating segment 406′. With reference to FIG. 26, an etch process, such as an anisotropic dry etch process, may be performed after the photolithography process to turn the second insulating layer 403 into the first extension portions 409 of the first insulating segments 406 and the second extension portions 409′ of the second insulating segment 406′.

In some embodiments, the first embedded portion 407 of the first insulating segment 406 may comprise a width D1, and the first extension portion 409 of the first insulating segments 406 may comprise a width D2 greater than the width D1 of the first embedded portion 407.

In some embodiments, the second embedded portion 407′ of the second insulating segments 405′ may comprise a width D3, and the second extension portion 409′ of the second insulating segment 406′ may comprise a width D4 greater than the width D3 of the second embedded portion 407′.

In some embodiments, the width D1 of the first embedded portion 407 is less than the width D3 of the second embedded portion 407′. In some embodiments, the width D2 of the first extension portion 409 is less than the width D4 of the second extension portion 409′.

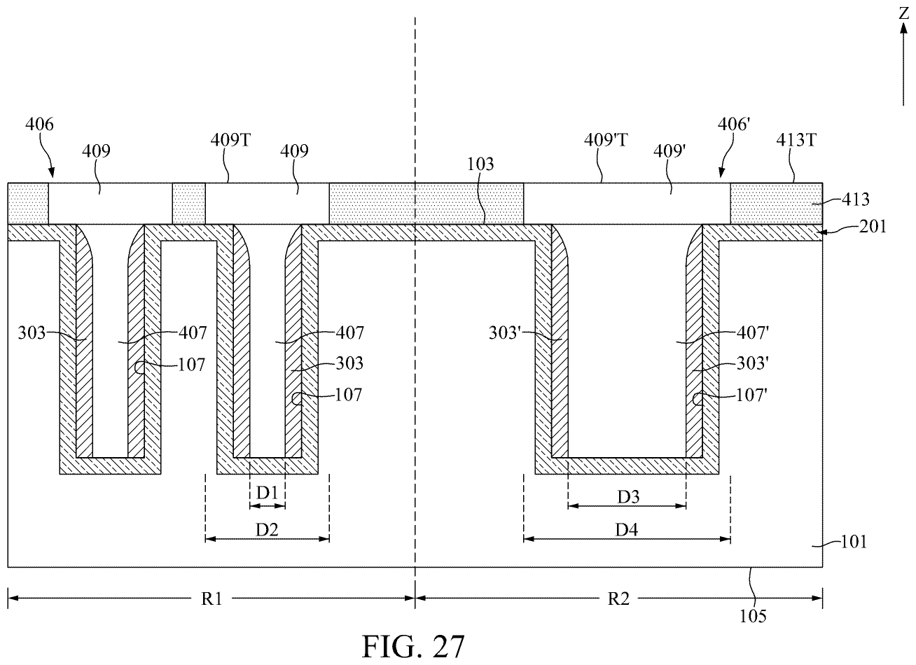

With reference to FIGS. 18 and 27, in step S29, a filling layer 413 may be formed over the substrate 101 to surround the first extension portions 409 of the first insulating segments 406 and the second extension portion 409′ of the second insulating segment 406′. In some embodiments, the filling layer 413 may be formed of silicon nitride. In some embodiments, the filling layer 413 may be formed by, for example, chemical vapor deposition, plasma-enhanced chemical vapor deposition, or other applicable deposition processes. A planarization process, such as chemical mechanical polishing, may be performed to remove a portion of the filling layer 413 until a top surface 409T of the first extension portion 409 of the first insulating segment 406 and a top surface 409′T of the second extension portion 409′ of the second insulating segment 406′ are exposed and provide a substantially flat surface for subsequent processing steps. In some embodiments, after the planarization process, a top surface 413T of the filling layer 413, the top surface 409T of the first extension portion 409 of the first insulating segment 406 and the top surface 409′T of the second extension portion 409′ of the second insulating segment 406′ are substantially coplanar.

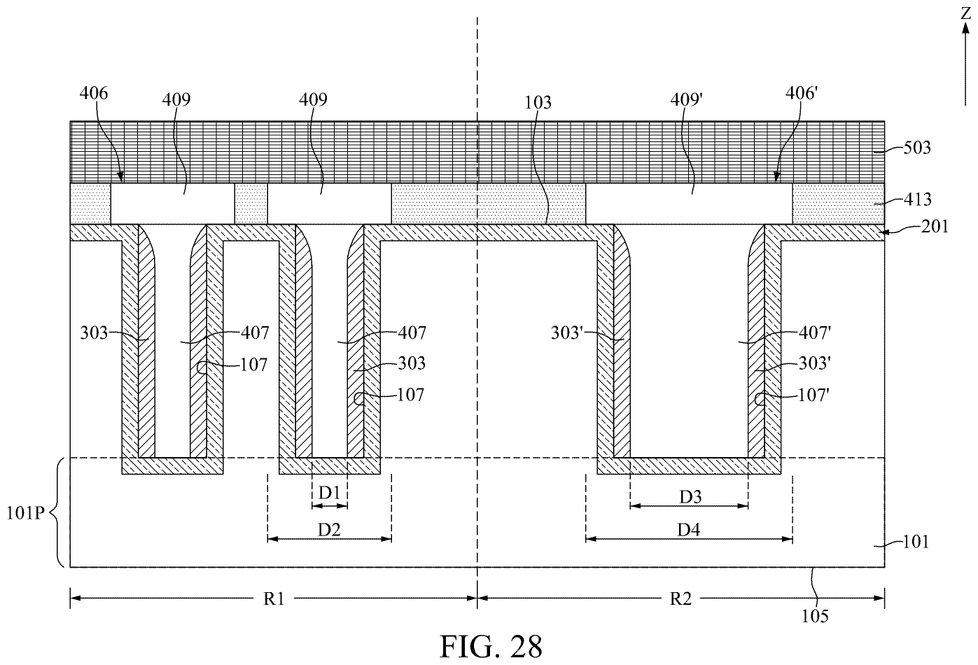

With reference to FIGS. 18 and 28, in step S31, a word line hard mask layer 503 may be formed over the first extension portion 409 of the first insulating segment 406, the second extension portion 409′ of the second insulating segment 406′, and the filling layer 413. Some materials and processes used to form the word line hard mask layer 503 are similar to, or same as, those used to form the word line hard mask layer 203 illustrated in FIG. 1 and FIGS. 14 to 17, in accordance with step S17 of the method 10, and details thereof are not repeated herein.

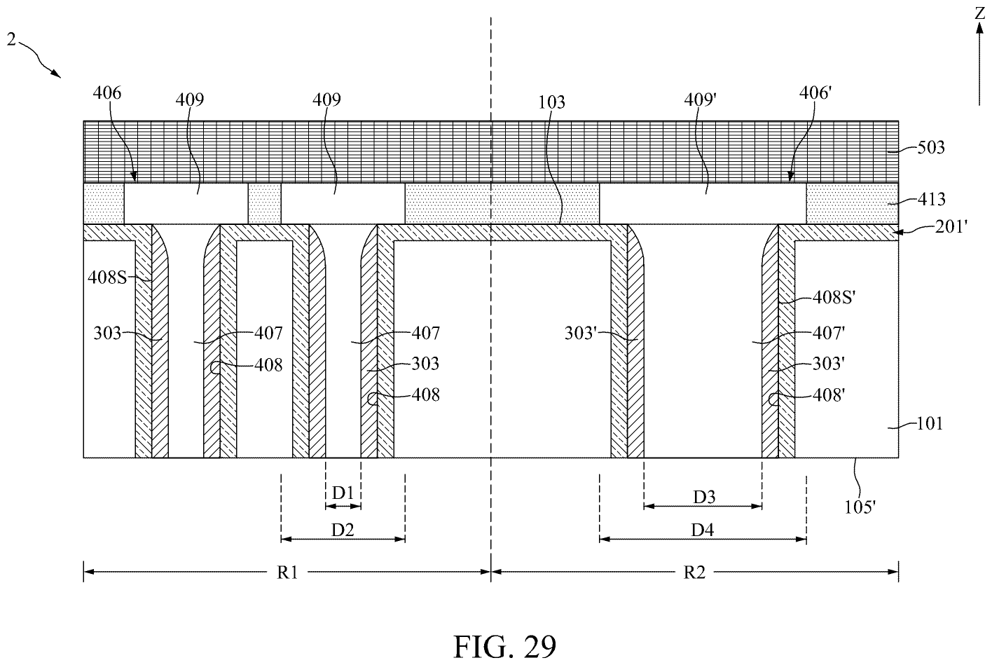

With reference to FIGS. 18 and 29, in step S33, apart (the part 101P in FIG. 28) of the substrate 101 may be removed from the second surface 105 until the plurality of first liners 303, the second liner 303′, the first embedded portions 407 of the first insulating segments 406, and the second embedded portion 407′ of the second insulating segment 406′ are exposed. In some embodiments, a removal process, such as chemical mechanical polishing, may be performed on the second surface 105 of the substrate 101 to expose the first liners 303, the second liner 303′, the first embedded portions 407, and the second embedded portion 407′. In some embodiments, after the removal of the part 101P of the substrate 101, the substrate 101 may have a modified second surface 105′, the doped region 201 may be turned into a modified doped region 201′, and the plurality of first trenches 107 and the second trench 107′ may be turned into a plurality of first through-substrate vias (TSVs) 408 and a second TSV 408′, respectively. It should be noted that the side surfaces 408S of the first TSVs 408 and the side surfaces 107S of the first trenches 107 are substantially the same, and the side surfaces 408S′ of the second TSV 408′ are substantially the same as the side surfaces 107S′ of the second trench 107′.

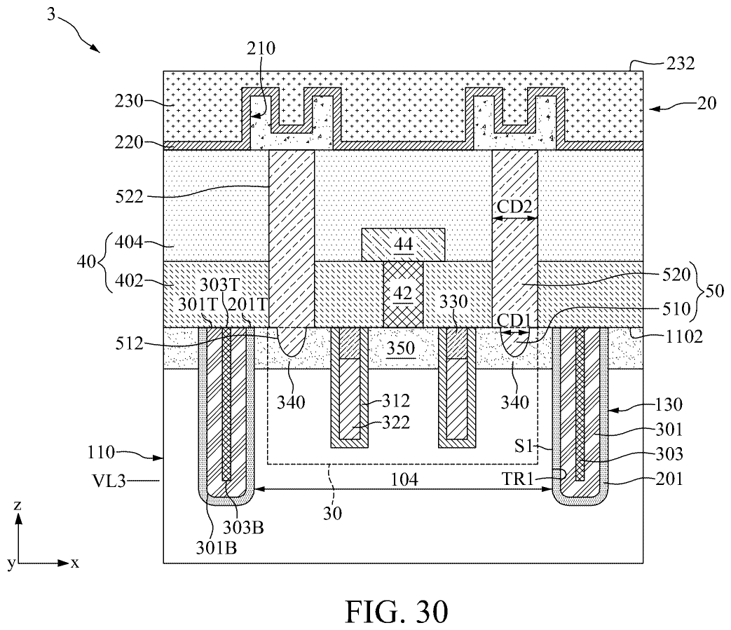

FIG. 30 illustrates, in a schematic cross-sectional view, a semiconductor device 3 in accordance with various embodiments of the present disclosure. The semiconductor device 10 may be a semiconductor memory device such as a dynamic random-access memory (DRAM) including one or more storage capacitors 20 and one or more access transistors 30 rendered conductive in response to a potential conducted thereon to couple the storage capacitors 20 to associated bit lines 44. The access transistors 30 shown in FIG. 30 are in a form of a recessed access device (RAD) transistor; however, in some embodiments, the access transistors 30 may be planar access device (PAD) transistors.

The semiconductor device 3 further comprises a dielectric layer 40 between the storage capacitors 20 and the access transistors 30 and a plurality of conductive features 50 extending from the storage capacitor 20 and into a substrate 110 to electrically couple the storage capacitors 20 to the access transistors 30. In other words, the conductive feature 50 serves as an electrical connection between the storage capacitor 20 and the respective access transistors 30, and the dielectric layer 40 insulates the conductive features 50. The bit line 44 may be buried in the dielectric layer 40 and electrically coupled to the access transistors 30 by at least one conductive plug 42 in the dielectric layer 40.

The storage capacitors 20 are disposed over the access transistors 30, and include a plurality of storage nodes 210 respectively contacting the conductive features 50, a capacitor insulator 220 encapsulating the storage nodes 210, and a top electrode 230 disposed on the capacitor insulator 220. More particularly, the storage nodes 210, disposed on the conductive features 50 and the dielectric layer 40, are spaced apart from and electrically isolated from each other. In some embodiments, the storage nodes 210 comprise a U-shaped configuration and function as lower electrodes of the storage capacitor 20. The capacitor insulator 220 can have a topology following a topology of the storage nodes 210 and the dielectric layer 40. The top electrode 230, functioning as an upper electrode of the storage capacitor 20, can have a substantially planar top surface 232; however, in some embodiments, the top electrode 230 may be a conformal layer.

The access transistors 30 are disposed in the substrate 110. The substrate 110 has one or more isolation features 130 defining active regions 104 in which the access transistors 30 are formed. The active regions 104 may be elongated island-shaped regions. For example, the active regions 104 can have an elliptical shape as viewed in a plan view. In addition, the active regions 104 may be disposed such that major axes (along a longitudinal direction) of the active regions 104 are not parallel to either an x-axis or a y-axis of an orthogonal coordinate system.

The isolation feature 130 may include a first filling layer 301 filling a trench TR1 disposed in the substrate 110, a second filling layer 303 disposed within the first filling layer 301, and a liner layer 201 lining an inner surface S1 of the trench TR1 and surrounding the first filling layer 301. In some embodiments, the first filling layer 301 and the liner layer 201 comprise a U-shaped cross-sectional profile. A top surface 301T of the first filling layer 301, a top surface 303T of the second filling layer 303, and a top surface 201T of the liner layer 201 are coplanar. In some embodiments, a bottom surface 303B of the second filling layer 303 is at a vertical level VL3 higher than a bottom surface 301B of the first filling layer 301.

The access transistors 30, in the active region 104, include a plurality of word lines 322 buried in the substrate 110 and covered by a capping layer 330, a plurality of insulative liners 312 disposed between the substrate 110 and the word lines 322 and between the substrate 110 and the capping layer 330, and a plurality of impurity regions 340 and 350 disposed on either side of the word lines 322. The word lines 322 extend along the y-axis and across the active regions 104 while the bit line 44 extends along the x-axis orthogonal to the y-axis. The active regions 104 may be oriented such that their major axes are oblique with respect to the word lines 322 and the bit lines 44. The active regions 104 may be sized such that one active region 104 intersects two word lines 322 and one bit line 44.

Still referring to FIG. 30, the impurity regions 340 and 350 serve as drain and source regions of the access transistors 30. The impurity regions 340 and 350 may be connected to an upper surface 1102 of the substrate 110. The impurity regions 340 are electrically coupled to the bottom electrodes 210 of the storage capacitor 20 by the conductive features 50, while the impurity region 350 is electrically coupled to the bit line 44 by the conductive plug 42. The word lines 322 function as gates in the access transistors 30 they pass through, and the bit line 44, formed using a damascene process, provides a signal to the access transistors 30.

The conductive features 50 are disposed on either side of the conductive plug 42. Because the active regions 104 have an elliptical shape, landing areas of the conductive features 50 are smaller than a landing area of the conductive plug 42. As a result, a contact area between the access transistor 30 and the conductive feature 50 is reduced, and a contact resistance therebetween is increased. In order to overcome such problem, the conductive features 50 of the present invention are designed to extend into the substrate 110.

More particularly, each conductive feature 50 comprises a lower portion 510 protruding into the impurity region 340 of the access transistor 30 and an upper portion 520 interposed between the upper surface 1102 of the substrate 110 and the storage capacitor 20. The lower portion 510 of the conductive feature 50, extending into the substrate 110, can increase the contact area of the conductive feature 50 and the substrate 110 in which the access transistor 30 is disposed. Therefore, the contact resistance between the access transistor 30 and the associated conductive feature 50 can be effectively reduced. The upper portion 520 of the conductive feature 50 is surrounded by the dielectric layer 40 comprised of a first dielectric layer 402 covering the substrate 110 and a second dielectric layer 404 sandwiched between the first dielectric layer 402 and the storage capacitor 20.

Still referring to FIG. 30, the lower portion 510 of the conductive feature 50, lower than the upper surface 1102 of the substrate 110, can have a first critical dimension CD1, and the upper portion 520 of the conductive feature 50, higher than the upper surface 1102 of the substrate 110, can have a second critical dimension CD2 greater than the first critical dimension CD1. In some embodiments, the first critical dimension CD1 gradually decreases at positions of increasing distance from the upper surface 1102 of the substrate 110, while the second critical dimension CD2 is constant. In particular, a peripheral surface 512 of the lower portion 510 of the conductive feature 50 is discontinuous with a peripheral surface 522 of the upper portion 520 of the conductive feature 50. Notably, the lower portion 510 and the upper portion 520 of the conductive feature 50, including polysilicon, are integrally formed.

One aspect of the present disclosure provides a semiconductor device. The semiconductor device comprises a substrate having a first surface and a second surface opposite to the first surface; a plurality of first through-substrate vias (TSVs) penetrating through the substrate; a plurality of first embedded portions of first insulating segments disposed in the first TSVs; and a plurality of first liners each disposed on a side surface of the first TSV and between the side surface of the first TSV and the first insulating segment. The first insulating segments and the first liners are exposed by the second surface of the substrate.

Another aspect of the present disclosure provides a semiconductor device. The semiconductor device comprises a substrate; at least one isolation feature disposed in the substrate, wherein the at least one isolation feature defines a plurality of active regions; a storage capacitor disposed over the substrate; an access transistor comprising a plurality of impurity regions disposed in the active region; and a conductive feature extending from the storage capacitor into the substrate for electrically coupling the storage capacitor to the access transistor.

Another aspect of the present disclosure provides a method for fabricating a semiconductor device. The method includes providing a substrate including a first region and a second region, wherein the substrate has a first surface and a second surface opposite to the first surface; forming a plurality of first trenches in the first region and a second trench in the second region; forming a doped region in the substrate; forming a plurality of first liners in the first trenches and a second liner in the second trench; forming a plurality of first embedded portions of first insulating segments in the first trenches and a second embedded portion of a second insulating segment in the second trench; forming a plurality of first extension portions of the first insulating segments over the first embedded portions and a second extension portion of the second insulating segment over the second embedded portion; and removing a part of the substrate from the second surface to expose the first insulating segments, the first liners, the second insulating segment and the second liner.

Embodiments of a semiconductor device are provided in the disclosure. In some embodiments, the semiconductor device comprises an isolation structure having a liner. Therefore, leakage current between source/drain regions may be avoided. As a result, overall device performance is improved, and a yield rate of the semiconductor device may be increased.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
at least one isolation feature disposed in the substrate, wherein the at least one isolation feature defines a plurality of active regions;
a storage capacitor disposed over the substrate;
an access transistor comprising a plurality of impurity regions disposed in the active region; and
a conductive feature extending from the storage capacitor into the substrate for electrically coupling the storage capacitor to the access transistor.

2. The semiconductor device of claim 1, wherein each of the at least one isolation features comprises:
a first filling layer filling a trench disposed in the substrate;
a second filling layer disposed within the first filling layer; and
a liner layer lining an inner surface of the trench and surrounding the first filling layer.

3. The semiconductor device of claim 2, wherein the first filling layer and the liner layer comprise a U-shaped cross-sectional profile.

4. The semiconductor device of claim 2, wherein a top surface of the first filling layer, a top surface of the second filling layer and a top surface of the liner layer are coplanar.

5. The semiconductor device of claim 4, wherein a bottom surface of the second filling layer is at a vertical level higher than a bottom surface of the first filling layer.

6. The semiconductor device of claim 1, wherein the conductive feature comprises a lower portion in the substrate and an upper portion interposed between the substrate and the storage capacitor, wherein the lower portion has a first critical dimension, and the upper portion has a second critical dimension greater than the first critical dimension.

7. The semiconductor device of claim 6, wherein the first critical dimension of the lower portion of the conductive feature gradually decreases at positions of increasing distance from the upper portion.

8. The semiconductor device of claim 1, wherein the access transistor further comprises:
a word line disposed in the substrate and across the active regions, wherein the impurity regions are disposed on either side of the word line; and
an insulative liner sandwiched between the substrate and the word line.

9. The semiconductor device of claim 1, further comprising:
a dielectric layer between the storage capacitor and the substrate to encapsulate the access transistor and enclose the conductive feature;
a bit line buried in the dielectric layer; and
a conductive plug extending from the bit line into the substrate for electrically coupling the bit line to the access transistor.

10. The semiconductor device of claim 1, wherein the storage capacitor comprises:
a plurality of storage nodes respectively contacting the conductive features;
a capacitor insulator encapsulating the storage nodes; and
a top electrode disposed on the capacitor insulator.
